(19) United States
(12) Patent Application Publication
(10) Pub. No.: US 2010/0091412 A1
(43) Pub. Date: Apr. 15, 2010

(54) Method for manufacturing a magneto-resistance effect element and magnetic recording and reproducing apparatus

(75) Inventors: Hiromi Yuasa, Kanagawa-ken (JP); Hideaki Fukuzawa, Kanagawa-ken (JP); Yoshihiko Fuji, Kanagawa-ken (JP); Shuichi Murakami, Tokyo (JP); Michiko Hara, Kanagawa-ken (JP); Kunliang Zhang, Fremont, CA (US); Min Li, Dubliln, CA (US); Erhard Schreck, San Jose, CA (US)

Correspondence Address: NIXON & VANDERHYE, P.C., 901 NORTH GLEBE ROAD, 11TH FLOOR, ARLINGTON, VA, 22203, US

(73) Assignees: KABUSHIKI KAISHA TOSHIBA, Tokyo (JP); TDK CORPORATION, Tokyo (JP)

(21) Appl. No.: 12/585,852

(22) Filed: Sep. 25, 2009

(30) Foreign Application Priority Data
Sep. 26, 2008 (JP) 2008-249237

(51) Int. Cl. G11B 5/33; B05D 5/12; C23C 16/513; H05H 1/24

(52) U.S. Cl. 360/313; 427/127; 427/535; 427/539; G9B/5.104

(57) ABSTRACT

A method for manufacturing a magneto-resistance effect element is provided. The magneto-resistance effect element includes a first magnetic layer including a ferromagnetic material, a second magnetic layer including a ferromagnetic material and a spacer layer provided between the first magnetic layer and the second magnetic layer, the spacer layer having an insulating layer and a conductive portion penetrating through the insulating layer. The method includes: forming a film to be a base material of the spacer layer; performing a first treatment using a gas including at least one of oxygen molecules, oxygen atoms, oxygen ions, oxygen plasma and oxygen radicals on the film; and performing a second treatment using a gas including at least one of helium ions, helium plasma, helium radicals, neon ions, neon plasma and neon radicals on the film submitted to the first treatment.

### CROSS-REFERENCE TO RELATED APPLICATIONS

This application is based upon and claims the benefit of priority from the prior Japanese Patent Application No. 2008-249237, filed on Sep. 26, 2008; the entire contents of which are incorporated herein by reference.

### BACKGROUND OF THE INVENTION

1. Field of the Invention

This invention relates to a method for manufacturing a magneto-resistance effect element and a magnetic recording and reproducing apparatus.

2. Background Art

Performance of a magnetic device, particularly such as a magnetic head is extremely enhanced by using Giant Magneto-Resistive Effect (GMR). Particularly, since a spin valve film (SV film) can exhibit a larger GMR effect, the SV film has developed the magnetic device such as a magnetic head and MRAM (Magnetic Random Access Memory).

The “spin valve” film is laminated films having such a structure as sandwiching a non-magnetic metal spacer layer between two ferromagnetic layers and is called as spin depending scattering unit. In the spin valve film, the magnetization of one ferromagnetic layer (often called as a “pinning layer” or “fixed magnetization layer”) is fixed by the magnetization of an anti-ferromagnetic layer and the magnetization of the other ferromagnetic layer (often called as a “free layer” or “free magnetization layer”) can be rotated in accordance with an external magnetic field. In the spin valve film, an electric resistance changes by varying a relative angle between the magnetizations of the pinning layer and the free layer. The value of the change in the electric resistance is called as MR (Magneto Resistance) variation ratio, and corresponds to an output of the element.

As a magneto-resistance effect element using the spin valve film, a CIP (Current In plane)-GMR element, a TMR (Tunneling Magneto Resistance) element and a CPP (Current Perpendicular to Plane)-GMR element are proposed. Among these elements, the CIP element was put to first practical use. In the CIP-GMR element, a sense current is flowed to the SV film in the direction parallel to the film surface thereof and it was in practice use during a period with a large head size. However, when a head size becomes small with increasing of the recording density in a HDD, a heat or the like become problem and the TMR element, in which a sense current is flowed to the film in the direction perpendicular to the film surface thereof was put to practical use next. In the TMR element has a merit of a small sense current and large output. However, the resistance in the TMR element is usually high because it uses a tunneling current through an insulating barrier. It will become problem not to decrease the resistance of the element in future when the recording density is increased and the head size is downsized.

To solve this problem, the CPP-GMR element has been proposed. The resistance of the element in the CPP-GMR element is low by nature, because it uses a magneto-resistance effect by a metal conduction. This is the merit of the CPP-GMR element comparing with the TMR element.

In a metallic CPP-GMR element in which the SV film is made of metallic films, the variation degree in resistance by the magnetization of the SV film becomes small so that to convert a weak magnetic field (for example, from a magnetic disk of high recording density) to an electric signal becomes difficult.

In contrast, such a CPP element using an oxide layer with a conductive portion along with the direction of film thickness (NOL: Nano-oxide layer) is proposed in JP-A 2002-208744 (KOKAI) (Patent document 1). In the CPP element, the element resistance and the MR variation degree of the element can be developed by means of CCP (Current-confined-path) effect. Hereinafter, this element is often called as a “CCP-CPP element”.

However, it is anticipated that from now, applications of magnetic recording devices will be further enlarged and higher-density recording will be achieved, and in this case, it becomes necessary to provide a magneto-resistance effect element having further higher output.

In the case of CCP-CPP element, because current is confined in a spacer, contribution of electric conduction in the conductive portion to GMR effect is very large. Specifically, it has been reported that a MR variation ratio becomes higher as decreasing the electric resistance of the conductive portion in IEEE Trans. Magn. 40 p. 2236, (2004) (Non-patent document 1).

As a means for realizing the CCP-CPP element, a method for manufacturing a spacer has been proposed in JP-A 2006-54257 (Kokai) (Patent document 2).

However, for achieving the MR variation ratio anticipated to be required in the future, further ingenuity is required.

As a method for decreasing amount of metal oxide, a reduction to cut bonds between the oxygen atoms and the metal atoms in the metal oxide is effective. As a method cutting the bonds, irradiation of Ar ions (Surf. Sci. 43, 625 (1974), Non-patent document 2), irradiation of electron beams and irradiation of X-ray (Surf. Sci. 213, 564 (1989), Non-patent document 3) are known. These methods are not adequate to be applied to the configuration of the purpose of this invention, because the energy in all of these methods is so high that the base material is etched or a mixing occurs before the cutting the bonds.

### SUMMARY OF THE INVENTION

According to an aspect of the invention, there is provided a method for manufacturing a magneto-resistance effect element having a first magnetic layer including a ferromagnetic material, a second magnetic layer including a ferromagnetic material and a spacer layer provided between the first magnetic layer and the second magnetic layer, the spacer layer having an insulating layer and a conductive portion penetrating through the insulating layer, the method including: forming a film to be a base material of the spacer layer; performing a first treatment using a gas including at least one of oxygen molecules, oxygen atoms, oxygen ions, oxygen plasma and oxygen radicals on the film; and performing a second treatment using a gas including at least one of helium ions, helium plasma, helium radicals, neon ions, neon plasma and neon radicals on the film submitted to the first treatment.

According to another aspect of the invention, there is provided a magnetic recording and reproducing apparatus comprising: a magnetic head assembly including a suspension, a the magneto-resistance effect element being mounted on one end of the suspension, and an actuator arm connected to other end of the suspension; and a magnetic recording medium, information being recorded in the magnetic recording medium by using the magneto-resistance effect element, the magneto-resistance effect element having a first magnetic layer including a ferromagnetic material, a second magnetic layer including a ferromagnetic material and a spacer layer provided between the first magnetic layer and the second magnetic layer, the spacer layer having an insulating layer and a conductive portion penetrating through the insulating layer, the magneto-resistance effect device being manufactured by a method including: forming a film to be a base material of the spacer layer; performing a first treatment using a gas including at least one of oxygen molecules, oxygen atoms, oxygen ions, oxygen plasma and oxygen radicals on the film; and performing a second treatment using a gas including at least one of helium ions, helium plasma, helium radicals, neon ions, neon plasma and neon radicals on the film submitted to the first treatment.

### BRIEF DESCRIPTION OF THE DRAWINGS

FIG. 1 is a flow chart illustrating a method for manufacturing a magneto-resistance effect element according to a first embodiment of this invention;

FIG. 2 is a schematic perspective view illustrating a configuration of a magneto-resistance effect element to which the method for manufacturing according to a first embodiment is applied;

FIG. 3 is a flow chart illustrating a specific example of the method for manufacturing according to a first embodiment of this invention;

FIGS. 4A to 4D are schematic sectional views illustrating the method for manufacturing according to a first embodiment of this invention;

FIGS. 5A and 5B are schematic sectional views illustrating the states of the relevant parts of the magneto-resistance effect element according to the first embodiment and the first comparative example;

FIGS. 6A, 6B and 6C are schematic views illustrating configurations of parts in the method for manufacturing according to the first embodiment of this invention;

FIG. 7 is a flow chart illustrating another method for manufacturing according to the first embodiment of this invention;

FIGS. 8A to 8H are schematic sectional views following step sequence illustrating another method for manufacturing according to a first embodiment of this invention;

FIG. 9 is a flow chart illustrating a method for manufacturing according to a second embodiment of this invention;

FIGS. 10A and 10B are schematic sectional views illustrating the effect of the method for manufacturing according to the second embodiment of this invention;

FIG. 11 is a flow chart illustrating another method for manufacturing according to the second embodiment of this invention;

FIG. 12 is a flow chart illustrating another method for manufacturing according to the second embodiment of this invention;

FIG. 13 is a flow chart illustrating another method for manufacturing according to the second embodiment of this invention;

FIG. 14 is a flow chart illustrating another method for manufacturing according to the second embodiment of this invention;

FIG. 15 is a flow chart illustrating another method for manufacturing according to the second embodiment of this invention;

FIG. 16 is a schematic view illustrating a configuration of a manufacturing apparatus used for the method for manufacturing according to the embodiments of this invention;

FIG. 17 is a schematic perspective view illustrating a configuration of another magneto-resistance effect element to which the method for manufacturing according to the embodiments of this invention is applied;

FIG. 18 is a schematic cross sectional view illustrating an application embodiment of the magneto-resistance effect element according to the embodiment of this invention;

FIG. 19 is a schematic cross sectional view illustrating an application embodiment of the magneto-resistance effect element according to the embodiments of this invention;

FIG. 20 is a schematic perspective view illustrating a configuration of magnetic head assembly according to the fourth embodiment of this invention;

FIG. 21 is a schematic perspective view illustrating a configuration of a magnetic recording and reproducing apparatus of a fifth embodiment of this invention;

FIG. 22 is a schematic view illustrating a configuration of a magnetic recording and reproducing apparatus according to a sixth embodiment of this invention;

FIG. 23 is a schematic view illustrating a configuration of another magnetic recording and reproducing apparatus according to a sixth embodiment of this invention;

FIG. 24 is a schematic view illustrating a configuration of another magnetic recording and reproducing apparatus according to a sixth embodiment of this invention; and

FIG. 25 is a schematic cross-sectional view taken on A-A′ line shown in FIG. 24.

### DETAILED DESCRIPTION OF THE INVENTION

Hereinafter, each of embodiments of this invention will now be described with reference to drawings.

The drawings are schematic or conceptual. And, the relationships between the thickness and width of each of components, specific coefficient of scales among members, and so forth are not necessarily the same as the actual ones. Moreover, even when the same portions are shown, the scales or specific coefficients are occasionally shown to be different from each other among the drawings.

Moreover, in the specification and each of the drawings, the same signs will be appended to the same components as described with respect to a previously presented drawing, and the detailed description thereof will be appropriately omitted.

### First Embodiment

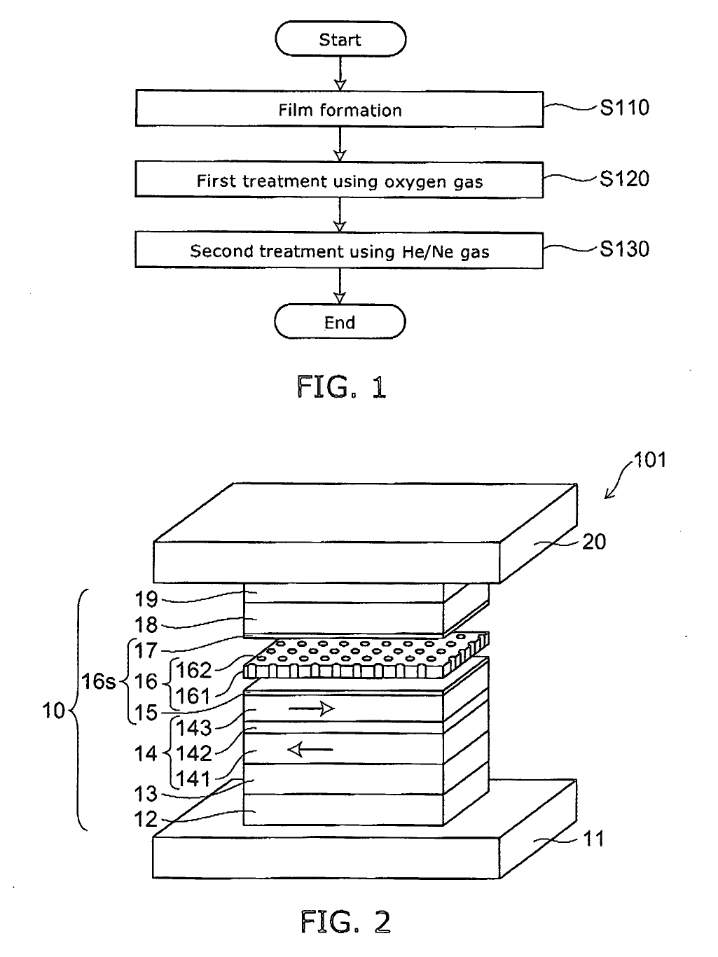

FIG. 1 is a flow chart illustrating a method for manufacturing a magneto-resistance effect element according to a first embodiment of this invention.

FIG. 2 is a schematic perspective view illustrating a configuration of a magneto-resistance effect element to which the method for manufacturing a magneto-resistance effect element according to a first embodiment of this invention is applied.

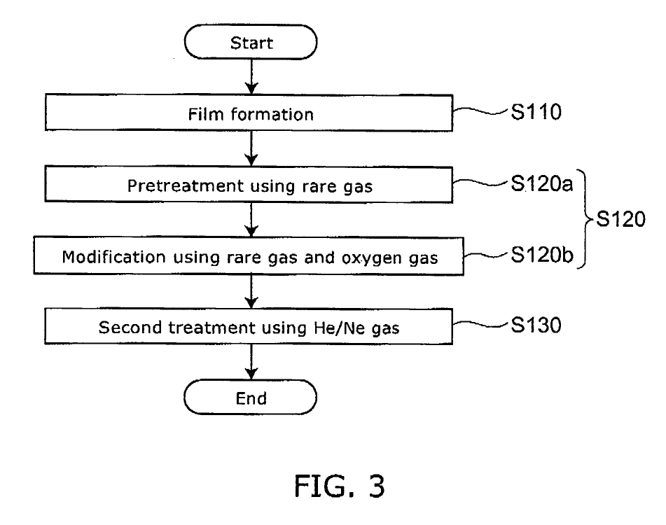

FIG. 3 is a flow chart illustrating a specific example of the method for manufacturing a magneto-resistance effect element according to a first embodiment of this invention.

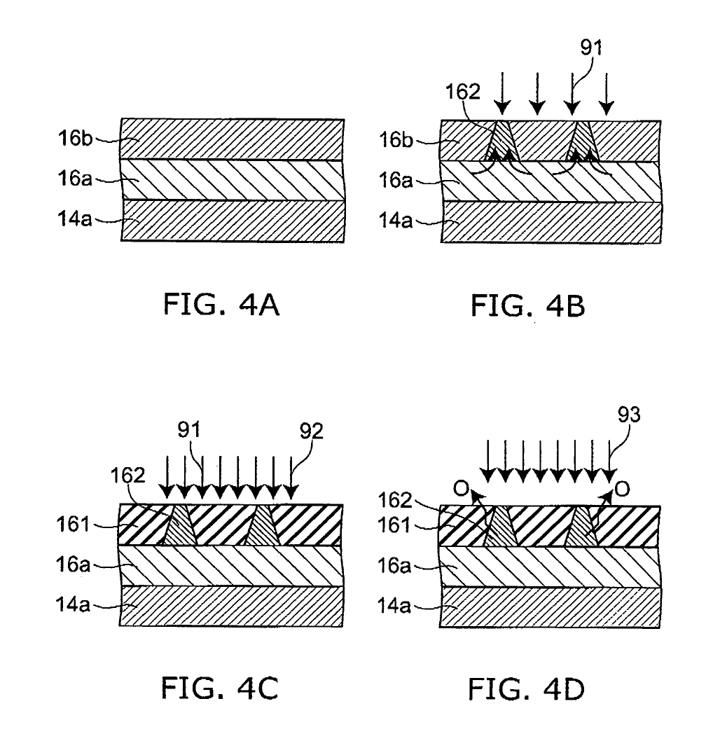

FIGS. 4A to 4D are schematic sectional views following step sequence illustrating the method for manufacturing a magneto-resistance effect element according to a first embodiment of this invention.

That is, FIG. 4A represents the first step, and FIG. 4B represents the step following the step of FIG. 4A, and FIG. 4C represents the step following the step of FIG. 4B, and FIG. 4D represents the step following the step of FIG. 4C.

At first, a magneto-resistance effect element 101 to which the method for manufacturing a magneto-resistance effect element according to this embodiment is applied is described.

As shown in FIG. 2, a magneto-resistance effect element 101 to which the method for manufacturing a magneto-resistance effect element according to this embodiment is applied is a CCP-CPP element whose spacer layer 16 has an insulating layer 161 and conductive portion 162 forming current pathways in the thickness direction of the insulating layer 161.

The magneto-resistance effective element 101 has a bottom electrode 11, a top electrode 20, and a magneto-resistance effective film 10 provided between the bottom electrode 11 and the top electrode 20. The magneto-resistance effective element 101 is formed on a substrate which is not shown.

The magneto-resistance effective film 10 includes an underlayer 12, a pining layer (antiferromagnetic layer) 13, a pinned layer 14, a bottom metallic layer 15, a spacer layer (CCP-NOL) 16 (an insulating layer 161 and a conductive portion 162), a top metallic layer 17, a free layer 18, and a cap layer (protective layer) 19 which are sequentially stacked and formed. The magneto-resistance effective element 101 is an example of a bottom-type CCP-CPP element in which the pinned layer 14 is located below the free layer 18. The pinned layer 14 has a bottom pinned layer 141, an antiparallel magnetic coupling layer (magnetic coupling layer) 142 and a top pinned layer 143.

Among them, the pinned layer 14, the bottom metallic layer 15, the spacer layer 16, and the top metallic layer 17, and the free layer 18 correspond to a spin valve film sandwiching the non-magnetic spacer layer between the two ferromagnetic layers, The entirety of the bottom metallic layer 15, the spacer layer (CCP-NOL) 16 and the top metallic layer 17 is defined as an extended spacer layer 16s. For clarifying the structural feature of the magneto-resistance effect element, the spacer layer 16 is shown under the condition that the spacer layer 16 is separated from the top and bottom layers (the bottom metallic layer 15 and the top metallic layer 17).

The spacer layer (CCP-NOL) 16 has the insulating layer 161 and the conductive portion 162 (metallic film) penetrating through the insulating layer 161.

As described above, The magneto-resistance effective element 101 has the pinned layer 14 to be a first magnetic layer, the free layer 18 to be a second magnetic layer, and a spacer layer 16 provided between the first magnetic layer and the second magnetic layer and including the insulating layer 161 and the conductive portion 162 (metallic layer) penetrating through the insulating layer 161.

For the pinned layer 14 and the free layer 18, various magnetic materials can be used. The pinned layer 14 and the free layer 18 will be described later.

In the spacer layer 16, the insulating layer 161 is mainly composed of metal oxide. On the other hand, the conductive portion 162 is mainly composed of metallic film.

For example, for the insulating layer 161, for example, Al₂O₃ is used.

The conductive portion 162 is a pathway flowing current vertically to the film surface of the spacer layer 16 and is for confining the current. The conductive portion 162 functions as a conductor passing through current in the vertical direction to the film surface of the insulating layer 161. That is, the spacer layer 16 has a current-confined-path structure (CCP structure) of the insulating layer 161 and the conductive portion 162, and the MR variation ratio is increased by the current-confined-path effect. For the conductive portion 162, metal such as Cu and forth is used.

This invention is not limited thereto and for the insulating layer 161 and the conductive portion 162, various materials to be described later can be used. Hereinafter, as an example, the case that the insulating layer 161 is made of Al₂O₃ and the conductive portion 162 is made of Cu will be described.

The bottom metallic layer 15 and the top metallic layer 17 are, for example, layers for enhancing crystallinity or the like of the various layers included in the magneto-resistance effect element 101 and are provided as necessary. Hereinafter, for simplifying the explanation, a case when the bottom metallic layer 15 and the top metallic layer 17 are not used will be described.

The conductive portion 162 is a region having drastically less content of oxygen than that in the insulating layer 161. For example, the content of oxygen in the insulating layer 161 is at least twice or lager than that in the conductive portion 162. The content of oxygen in the conductive portion 162 is not 0%, and, for example, the conductive portion 162 includes larger amount of oxygen than that of the case in which the insulating layer does not exist circumferentially.

The conductive portion 162 has generally crystal phase but its orientation is worse than that of continuous film or metal of bulk. In the case of CCP-CPP element, as the amount of oxygen of the conductive portion 162 decreases, the specific resistance of the conductive portion 162 is decreased and higher MR variation ratio is obtained.

Meanwhile, is desired that the resistivity of the insulating layer 161 is high, because the current-confined-path effect becomes high as the difference between the electric resistivity of the insulating layer 161 and that of the conductive portion 162 becomes large.

Therefore, it is desired that the conductive portion 162 has smaller amount of the oxygen impurities and high orientation property.

The method for manufacturing a magneto-resistance effect element according to this embodiment is a method for decreasing the content of impurities of oxygen in the conductive portion 162. Thereby, high MR variation ratio is obtained. Specially, the method decreases the amount of the oxygen existing in the region from shallow portion to deep portion in the conductive portion 162.

As described later, also by improving crystallinity of the conductive portion 162, higher MR variation ratio can be obtained. According to the method for manufacturing a magneto-resistance effect element according to this embodiment, crystallinity can be improved, and the high MR variation ratio is also realized from this aspect.

As shown in FIG. 1, in the method for manufacturing a magnetic-resistive effect element according to this embodiment, the following steps are performed between the step of forming the first magnetic layer including ferromagnetic material and the step of forming the second magnetic layer including the ferromagnetic material.

That is, first of all, a film to be a base material of the spacer layer 16 is formed (Step S110).

As shown in FIG. 4A, for example, on a layer 14a including the first magnetic layer, a first metallic film 16a to be the conductive portion 162 and a second metallic layer 16b to be the insulating layer 161 are film-formed and stacked. The first metallic film 16a is, for example, made of Cu. The second metallic film 16b is made of Al. The second metallic film 16b may be made of AlCu.

And, the films (the first metallic film 16a and the second metallic film 16b) are submitted to a first treatment using a gas including at least one of oxygen molecules, oxygen atoms, oxygen ions, oxygen plasma and oxygen radicals (Step 120). Herein after, the above mentioned treatment is described with an abbreviated expression of “treatment using oxygen”.

For example, as shown in FIG. 4B, first PIT (Pre Ion Treatment) by an Ar ion beam 91 is performed (Step 120a illustrated in FIG. 3). Then, as shown in FIG. 4C, IAO (Ion Assisted Oxidation) by an oxygen ion beam 92 is performed (Step S120b illustrated in FIG. 3). As described above, the second step (Step S120) performing the first treatment by using an oxygen gas may include the PIT step (Pretreatment step by using a rare gas: Step S120a) and the IAO step (Modification step by using a rare gas and an oxygen gas: Step S120b).

By PIT, portions of the first metallic film 16a in the lower side are sucked up to the side of second metallic film 16b. And, the portions of the first metallic film 16a penetrate through the second metallic film 16b to form the conductive portion 162. And, by the IAO by using the oxygen gas (oxygen ion beam 92 in this case), the first metallic film 16a and the second metallic film 16b are submitted to oxidizing treatment.

In this case, by selecting materials used in the first metallic film 16a and the second metallic film 16b, selective oxidation is performed. For the first metallic film 16a to be the conductive portion 162, a material having high oxidation generation energy is used, and for the second metallic film 16b to be the Insulating layer 161, a material having low oxidation generation energy is used. That is, in the conductive portion 162, a material that is hard to be oxidized and easy to be reduced more than that of the insulating layer 161 is used.

In this specific example, the second metallic film 16b made of Al is oxidized to be Al₂O₃ and the insulating layer 161 is formed. And, the first metallic film 16a made of Cu is relatively hard to be oxidized, and a large amount thereof remains as the metal. However, a part thereof is oxidized and CuO is generated. For decreasing the electrical resistivity of the conductive portion 162, it is desirable to decrease the amount of CuO as less as possible.

As a method for decreasing amount of CuO, a reduction to cut bonds between the oxygen atoms and the metal atoms in the metal oxide is effective. As a method for cutting the bonds, irradiation of Ar ions (Surf. Sci. 43, 625 (1974)), irradiation of electron beams and irradiation of X-ray (Surf. Sci. 213, 564 (1989)) are known.

These methods cannot be adapted to the method for manufacturing of the embodiment, because the energy in all of these methods is so high that the base material is etched or some mixing occur before the cutting the bonds.

On the other hand, by irradiation of rare gas that is light element, a suitable energy can be provided to the insulating layer 161 and conductive portion 162 compared with Ar ions. This comes from that the penetration depth into the object of the light rare gas is longer than that of the Ar gas. In the case of Ar gas, a strong energy is needed to exert the reduction effect cutting the oxygen-bond in the deep portion of the spacer layer 16 with a thickness from 1.5 nm to 5 nm and it comes to give damages to the conductive portion 162 and the insulating layer 161. On the other hand, in the case of He or Ne, the energy can reach to the deep portion with several nanometers and a uniform reduction in the depth direction can be realized.

Therefore, it is able to cut the bonds between Cu and oxygen while suppressing the damage in the conductive portion 162 and the insulating layer 161. Oxygen being cut off is released to the treatment chamber and is exhausted to the outside of the treatment chamber by the exhausting system.

From the above-described reasons, the above-described films (the first metallic film 16a, the second metallic film 16b, and mixture of the insulating layer 161 and conductive portion 162) submitted to the above-described first treatment is submitted to a second treatment by using at least one of helium ions, helium plasma, helium radicals, neon ions, neon plasma and neon radicals (Step S130). Herein after, the above mentioned treatment is described with an abbreviated expression of “treatment using light rare gas”.

As shown in FIG. 4D, the above-described films are irradiated with a helium ion beam 93, and thereby, CuO generated by oxidation of the first metallic film 16a is reduced and changed to Cu. That is the following reactions occur.

2CuO→Cu₂O+O (1)

Cu₂O→2Cu+O₂ (2)

By the collision energy of the helium ion beam 93, the bonds between Cu and oxygen are cut and CuO can be reduced. And this reducing effect is exerted from shallow portion to deep portion of the conduction portion 162 uniformly.

At this time, also A₂O₃ to be the insulating layer 161 is submitted to the reducing treatment, but by appropriately selecting the condition such that A₂O₃ is not substantially reduced and CuO is reduced, the resistance of the conductive portion 162 can be decreased with substantially no adverse effect to the insulating characteristics of the insulating layer 161.

As described above, according to the method for manufacturing a magneto-resistance effect element according to this embodiment, the oxide of the conductive portion 162 generated in forming the insulating layer 161 and conductive portion 162 is reduced, and the amount of oxygen impurities in the conductive portion is decreased. Thereby, the resistance of the conductive portion 162 is decreased and the current-confined-path effect is effectively exerted. Thereby, the CCP-CPP type magneto-resistance effect element having higher MR variation ratio can be obtained.

In this method, because ions, plasma and radicals of light rare gas like helium or neon are used, the reducing effect is exerted from the surface to deep portion of the conduction portion 162 even the treatment is performed on the surface of the conductive portion 162. Thereby, according to the method for manufacturing a magneto-resistance effect element according to this embodiment, the amount of oxygen from shallow portion to deep portion of the conductive portion 162 is effectively decreased and the conductivity of the conductive portion 162 is improved. Moreover, the method may improve the crystallinity to be uniform from shallow portion to deep portion of the conductive portion 162.

In the second treatment, most oxygen whose bonds are cut, are released into vacuum, but a portion of thereof may remain in the spacer layer 16 and cause the reoxidization of the surrounding metal. By it becomes difficult to decrease sufficiently the amount of the oxygen impurities in the conductive portion 162 obtained finally. For these problems, by heating the substrate or irradiating of Ar ion beams or Ar plasma, the oxygen whose bonds are cut can be effectively released into vacuum from the conductive portion 162.

In the above description, as the method for converting the second metallic film 16b into the insulating layer 161, an example of performing IAO by the oxygen ion beam 92 has been described. However, this invention is not limited thereto, and method using at least one of oxygen molecules, oxygen atoms, oxygen ions, oxygen plasma and oxygen radicals can be used for the method for converting the second metallic film 16b into the insulating layer 161, and the method is discretional.

For example, a method of exposing the first metallic film 16a and the second metallic film 16b to an oxygen gas is also possible. In the case that the first metallic film 16a is Cu and the second metallic film 16b is Al, the oxygen exposure amount is appropriately, for example, from 10000 Langmuires to 50000 Langmuires. If smaller than 10000 Langmuires, oxidation of the second metallic film 16b is insufficient. If larger than 50000 Langmuires, oxidation of the first metallic film 16a begins.

In the first treatment, after IAO, treatment of irradiating rare gas ion or rare gas plasma or treatment of heating the substrate may be added. Thereby, separation between the insulating layer 161 and the conductive portion 162 can be more promoted. As the rare gas, at least any one of He, Ne, Ar, Xe, and Kr may be used, and in the case of irradiating the rare gas as ion beam, it is preferable that the beam voltage applied to the grid is 50 V or less and the irradiation time is 1 minute or less. In the case of irradiating the rare gas as RF plasma, it is preferable that the bias power is 10 W or less and the irradiation time is 1 minute or less. In the case of heating, the upper limit of the substrate temperature may be 80° C. The reason why such an upper limit is set is to prevent CCP-NOL from being broken.

### Comparative Example

In a method for manufacturing a magneto-resistance effect element of a comparative example, the third step (Step S130) illustrated in FIG. 1 is not performed. In the magneto-resistance effect element manufactured by the method of the first comparative example, the second metallic film 16b is oxidized by the first treatment of oxidizing in the second step (Step S120), and specifically, CuO is generated from Cu, and as a result, a large amount of oxygen impurities exists in the conductive portion 162. As a result, the resistivity of the conductive portion is high and the current-confined-path effect is suppressed and MR variation ratio is low.

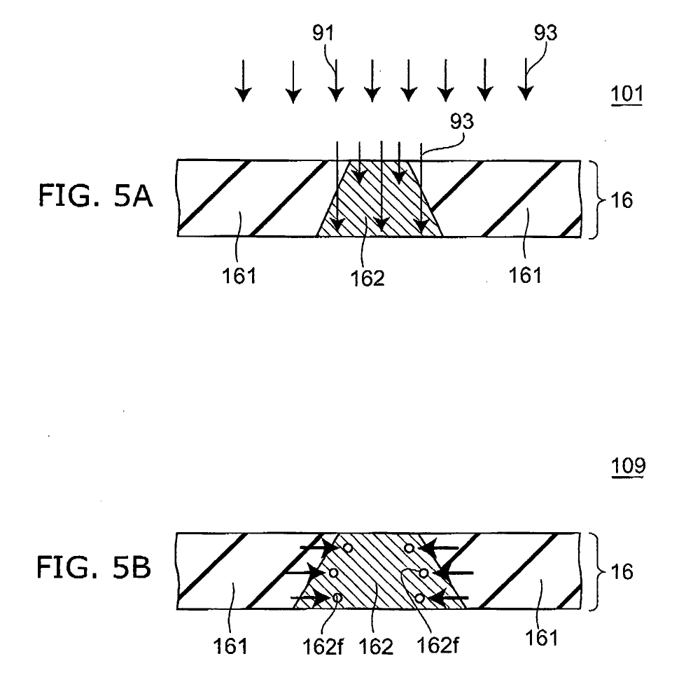

FIGS. 5A and 5B are schematic sectional views illustrating the states of the relevant parts of the magneto-resistance effect element according to the first embodiment of this invention and the magneto-resistance effect element according to the first comparative example.

That is, FIG. 5A illustrates the state of the spacer layer 16 of the magneto-resistance effect element 101 according to this embodiment, and FIG. 5B illustrates the state of the spacer layer 16 of the magneto-resistance effect element 109 of the comparative example.

As shown in FIG. 5B, in the case of the magneto-resistance effect element 109 of the comparative example, Cu to be the conductive portion 162 is oxidized by the first treatment and CuO is generated even with small amount. Since the oxidization in the first treatment is performed on the upper portion of the conductive portion 162, the oxygen comes in the conductive portion 162 from the upper face (upper surface). But, in addition to this, oxygen atoms 162f diffuse into the conductive portion 162 from Al₂O₃ to be the insulating layer 161, and as a result, oxygen impurities may be contained in portions from the shallow portion to the deep portion in the conductive portion 162. For example, depending on the material used for the first metallic film 16a and the second metallic film 16b, the film thickness thereof, the condition of film formation and the condition of the first treatment using oxygen, the oxygen impurities may be contained in portions from the shallow portion to the deep portion in the conductive portion 162. Thus, depending on the specifications of the spacer layer 16 or the condition of the first treatment, some amount of oxygen is contained in the conductive portion 162 and the conductivity of the conductive portion 162 is decreased, as a result, MR variation ratio is decreased.

By contrast, as shown in FIG. 5A, in the magneto-resistance effect element 101 manufactured by the method for manufacturing a magneto-resistance effect element according to this embodiment, if Cu to be the conductive portion 162 is oxidized by the first treatment and CuO is generated, CuO is reduced by the subsequent second treatment by using light rare gas uniformly in the region from the sallow portion to the deep portion, and CuO does not substantially remain. That is, if oxygen atoms 162f diffuse into the conductive portion 162 from Al₂O₃ to be the insulating layer 161, the reduction effect by the second treatment using light rare gas is high even in the deep portion because light rare gas penetrates easily. Thereby, the purity of the conductive portion 162 is high and less oxygen is included. And the crystallinity can be improved. Thereby, the resistivity of the conductive portion 162 can be decreased.

As described above, according to the method for manufacturing a magneto-resistance effect element according to this example, by reducing the conductive portion 162 and decreasing the resistivity, the CCP-CPP type magneto-resistance effect element having high MR variation ratio can be obtained.

An example of the configuration of a magneto-resistance effect element to which the method for manufacturing a magneto-resistance effect element according to the embodiment of this invention is applied will be described by referring FIG. 2.

The bottom electrode 11 functions as an electrode for flowing a current in the direction perpendicular to the spin valve film. The current can be flowed through the spin valve film in the direction perpendicular to the film surface thereof by applying a voltage between the bottom electrode 11 and the top electrode 20. The change in resistance of the spin valve film originated from the magneto-resistance effect can be detected by utilizing the current. In other words, the magnetization detection can be realized by the current flow. The bottom electrode 11 is made of a metallic layer with a relatively small electric resistance for flowing the current to the magneto-resistance effect element sufficiently. For example NiFe, Cu or the like are used for the bottom electrode.

The underlayer 12 may be composed of a buffer layer 12a (not shown) and a seed layer 12b (not shown). The buffer layer 12a can be employed for the compensation of the surface roughness of the bottom electrode 11. The seed layer 12b can be employed for controlling the crystalline orientation and the crystal grain size of the spin valve film to be formed on the underlayer 12.

The buffer layer 12a may be made of Ta, Ti, W, Zr, Hf, Cr or an alloy thereof. The thickness of the buffer layer 12a is preferably set within 2 to 10 nm, more preferably set within 3 to 5 nm. If the buffer layer 12a is formed too thin, the buffer layer 12a can exhibit the inherent buffering effect. If the buffer layer 12a is formed too thick, the DC resistance not contributing to the MR variation may be increased. If the seed layer 12b can exhibit the buffering effect, the buffer layer 12a may be omitted. In a preferable example, the buffer layer 12a is made of a Ta layer with a thickness of 3 nm.

The seed layer 12b may be made of any material controllable for the crystalline orientation of (a) layer(s) to be formed thereon. For example, the seed layer 12b may be made preferably of a metallic layer with an fcc-structure (face-centered cubic structure), an hcp-structure (hexagonal close-packed structure) or a bcc-structure (body-centered cubic structure). Concretely, the seed layer 12b may be made of Ru with hcp-structure or NiFe with fcc-structure so that the crystalline orientation of the spin valve film to be formed thereon can be rendered an fcc (111) faced orientation. In this case, the crystalline orientation of the pinning layer 13 (e.g., made of PtMn) can be rendered an fct-structure (face-centered tetragonal structure)-regulated orientation or a bcc (110) faced orientation. Moreover, Cr, Zr, Ti, Mo, Nb, W or an alloy layer thereof can be used.

In order to exhibit the inherent seeding function of the seed layer 12b of enhancing the crystalline orientation sufficiently, the thickness of the seed layer 12b is set preferably within 1 to 5 nm, more preferably within 1.5 to 3 nm. In a preferable example, the seed layer 12b may be made of a Ru layer with a thickness of 2 nm.

The crystalline orientation for the spin valve film and the pinning layer 13 can be measured by means of X-ray diffraction. For example, the FWHMs (full width at half maximum) in X-ray rocking curve of the fcc (111) peak of the spin valve film, the fct (111) peak or the bcc (110) peak of the pinning layer 13 (PtMn) can be set within a range of 3.5 to 6 degrees, respectively under good crystallinity. The dispersion of the orientation relating to the spin valve film and the pinning layer can be recognized by means of diffraction spot using cross section TEM.

The seed layer 12b may be made of a NiFe-based alloy (e.g., Ni_{X}Fe_{100-X:} X=90 to 50%, preferably 75 to 85%) layer of a NiFe-based non-magnetic ((Ni_{X}Fe_{100-X})_{100-Y}X_{Y:} X=Cr, V, Nb, Hf, Zr, Mo)) layer. In the latter case, the addition of the third element “X” renders the seed layer 12b non-magnetic. The crystalline orientation of the seed layer 12b of the NiFe-based alloy can be enhanced easily so that the FWHM in X-ray rocking curve can be rendered within a range of 3-5 degrees.

The seed layer 12b functions not only as the enhancement of the crystalline orientation, but also as the control of the crystal grain size of the spin valve film. Concretely, the crystal grain size of the spin valve film can be controlled within a range of 5 to 40 nm so that the fluctuation in performance of the magneto-resistance effect element can be prevented, and thus, the higher MR variation ratio can be realized even though the magneto-resistance effect element is downsized.

The crystal grain size of the spin valve film can be determined on the crystal grain size of the layer formed on the seed layer 12b by means of cross section TEM. In the case of a bottom type spin valve film where the pinning layer 14 is located below the spacer layer 16, the crystal grain size of the spin valve film can be determined on the crystal grain size of the pinning layer 13 (antiferromagnetic layer) or the pinned layer 14 (fixed magnetization layer) to be formed on the seed layer 12b.

With a reproducing head in view of high recording density, the element size is set to 100 nm or below, for example. Therefore, if the crystal grain size is set larger for the element size, the element characteristics may be fluctuated. In this point of view, it is not desired that the crystal grain size of the spin valve film is set larger than 40 nm. Concretely, the crystal grain size of the spin valve film is set preferably within 5 to 40 nm, more preferably within 5 to 20 nm.

Too large crystal grain size may cause the decrease of the number of crystal grain per element surface so as to cause fluctuation in characteristics of the reproducing head. With the CCP-CPP element forming a current confining path, it is not desired to increase the crystal grain size than a prescribed grain size. In contrast, too small crystal grain size may deteriorate the crystalline orientation. In this point of view, it is required that the crystal grain size is determined in view of the upper limited value and the lower limited value, e.g., within a range of 5 to 20 nm.

With the use of MRAM, however, the element size may be increased to 100 nm or over so that the crystal grain size can be increased to about 40 nm without the above-mentioned problem. Namely, if the seed layer 12b is employed, the crystal grain size may be increased than the prescribed grain size.

In order to set the crystal grain size within 5 to 20 nm, the seed layer 12b may be made of a Ru layer with a thickness of 2 nm or a NiFe-based non-magnetic ((Ni_{X}Fe_{100-X})_{100-Y}X_{Y:} X=Cr, V, Nb, Hf, Zr, Mo, preferably y=0 to 30%)) layer.

In contrast, in the case that the crystal grain size is increased more than 40 nm and thus, is rendered coarse, the content of the third additive element is preferably increased more than the value described above. For example, with NiFeCr alloy, the content of Cr is preferably set within 35 to 45% so as to set the composition of the NiFeCr alloy to the composition exhibiting intermediate phase structure between the fcc-structure and the bcc-structure. In this case, the resultant NiFeCr layer can have the bcc-structure.

As described above, the thickness of the seed layer 12b is set preferably within 1 to 5 nm, more preferably within 1.5 to 3 nm. Too thin seed layer 12b may deteriorate the crystalline orientation controllability. In contrast, too thick seed layer 12b may increase the DC resistance of the element and rough the interface for the spin valve film.

The pinning layer 13 functions as applying the unidirectional anisotropy to the ferromagnetic layer to be the pinned layer 14 on the pinning layer 13 and fixing the magnetization of the pinned layer 14. The pinning layer 13 may be made of an antiferromagnetic material such as PtMn, PdPtMn, IrMn, RuRhMn, FeMn and NiMn. In view of the use of the element as a high density recording head, the pinning layer 13 is preferably made of IrMn because the IrMn layer can apply the unidirectional anisotropy to the pinned layer 14 in comparison with the PtMn layer even though the thickness of the IrMn layer is smaller than the thickness of the PtMn layer. In this point of view, the use of the IrMn layer can reduce the gap width of the intended element for high density recording.

In order to apply the unidirectional anisotropy with sufficient intensity, the thickness of the pining layer 13 is appropriately controlled. In the case that the pinning layer 13 is made of PtMn or PdPtMn, the thickness of the pinning layer 13 is set preferably within 8 to 20 nm, more preferably within 10 to 15 nm. In the case that the pinning layer 13 is made of IrMn, the unidirectional anisotropy can be applied even though the thickness of the pinning layer 13 of IrMn is set smaller than the thickness of the pinning layer 13 of PtMn. In this point of view, the thickness of the pinning layer 13 of IrMn is set preferably within 3 to 12 nm, more preferably within 4 to 10 nm. In a preferred embodiment, the thickness of the IrMn pinning layer 13 is set to 7 nm.

The pinning layer 13 may be made of a hard magnetic layer instead of the antiferromagnetic layer. For example, the pinning layer 13 may be made of CoPt (Co=50 to 85%), (CO_{X}Pt_{100-X})_{100-Y} Cr_{Y:} X=50 to 85%, Y=0 to 40%) or FePt (Pt=40 to 60%). Since the hard magnetic layer has a smaller specific resistance, the DC resistance and the surface resistance RA of the element can be reduced.

In a preferred embodiment, the pinned layer 14 is formed as a synthetic pinned layer composed of the bottom pinned layer 141 (e.g., CO₉₀Fe₁₀ 3.5 nm), the magnetic coupling layer 142 (e.g., Ru) and the top pinned layer 143 (e.g., (Fe₅₀CO₅₀ 1 nm/Cu 0.25 nm)×2/Fe₅₀CO₅₀ 1 nm). The pinning layer 13 (e.g., IrMn layer) is coupled via magnetic exchange with the bottom pinned layer 141 formed on the pinning layer 13 so as to apply the unidirectional anisotropy to the bottom pinned layer 141. The bottom pinned layer 141 and the top pinned layer 143 which are located under and above the magnetic coupling layer 142, respectively, are strongly magnetically coupled with one another so that the direction of magnetization in the bottom pinned layer 141 becomes anti-paralleled to the direction of magnetization in the top pinned layer 143.

The bottom pinned layer 141 may be made of CO_{X}Fe_{100-X} alloy (x=0 to 100), Ni_{X}Fe_{100-X} (X=0 to 100) or an alloy thereof containing a non magnetic element. The bottom pinned layer 141 may be also made of a single element such as Co, Fe, Ni or an alloy thereof.

It is desired that the magnetic thickness (saturated magnetization Bs×thickness t (Bs·t)) of the bottom pinned layer 141 is set almost equal to the one of the top pinned layer 143. Namely, it is desired that the magnetic thickness of the top pinned layer 143 corresponds to the magnetic thickness of the bottom pinned layer 141. For example, when the top pinned layer 143 of (Fe₅₀CO₅₀ 1 nm/Cu 0.25 nm)×2/Fe₅₀CO₅₀ 1 nm is employed, the magnetic thickness of the top pinned layer 143 is set to 2.2 T×3 nm=6.6 Tnm because the saturated magnetization of the top pinned layer 143 is about 2.2 T. When the bottom pinned layer 141 of CO₉₀Fe₁₀ is employed, the thickness of the bottom pinned layer 141 is set to 6.6 Tnm/1.8 T=3.66 nm for the magnetic thickness of 6.6 Tnm because the saturated magnetization of Co_{90Fe10} is about 1.8 T. In this point of view, it is desired that the thickness of the bottom pinned layer 141 made of CO_{90Fe10} is set to about 3.6 nm. When the pinned layer 13 IrMn, it is preferable to increase the Fe concentration in the bottom pinned layer 141 from CO₉₀Fe₁₀.

The thickness of the bottom pinned layer 141 is preferably set within 1.5 to 4 nm in view of the magnetic strength of the unidirectional anisotropy relating to the pinning layer 13 (e.g., IrMn layer) and the magnetic strength of the antiferromagnetic coupling between the bottom pinned layer 141 and the top pinned layer 143 via the magnetic coupling layer 142 (e.g., Ru layer). Too thin bottom pinned layer 141 causes the decrease of the MR variation ratio. In contrast, too thick bottom pinned layer 141 causes the difficulty of obtaining the unidirectional anisotropy magnetic field requiring for the operation of the element. In a preferred embodiment, the bottom pinned layer 141 may be made of a CO₇₅Fe₂₅ layer with a thickness of 3.6 nm.

The magnetic coupling layer 142 (e.g., Ru layer) causes the antiferromatic coupling between the bottom pinned layer 141 and the top pinned layer 143 which are located under and above the magnetic coupling layer 142. In the case that the magnetic coupling layer 142 is made of the Ru layer, the thickness of the Ru layer is preferably set within 0.8 to 1 nm, Only if the antiferromagnetic coupling between the pinned layers located under and above the magnetic coupling layer 142 can be generated, the magnetic coupling layer 142 may be made of another material except Ru or the thickness of the magnetic coupling layer 142 may be varied within 0.3 to 0.6 nm instead of the thickness range of 0.8 to 1 nm. The former thickness range of 0.3 to 0.6 nm corresponds to the first peak of RKKY (Runderman-Kittel-Kasuya-Yoshida), and the latter thickness range of 0.8 to 1 nm corresponds to the second peak of RKKY. In a preferred embodiment, the magnetic coupling layer 142 may be made of the Ru layer with a thickness of 0.9 nm so as to realize the antiferromagnetic coupling for the pinned layers stably.

The top pinned layer 143 may be made of (Fe₅₀CO₅₀ 1 nm/Cu 0.25 nm)×2/Fe₅₀Co₅₀ 1 nm. The top pinned layer 143 composes the spin dependent scattering unit. The top pinned layer 143 can contribute directly to the MR effect, and thus, the material and thickness of the top pinned layer 143 are important so as to realize a high MR variation ratio. The magnetic material of the top pinned layer 143 to be positioned at the interface for the CCP-NOL layer 16 is important in view of the contribution of the spin dependent interface scattering.

Then, the effect/function of the top pinned layer 143 of the Fe₅₀CO₅₀ layer with bcc-structure will be described. In this case, since the spin dependent interface scattering is enhanced, the MR variation ratio can be enhanced. As the FeCo-based alloy with bcc-structure, a CO_{X}Fe_{100-X} alloy (X=30 to 100) or a similar CoFe-based alloy containing an additive element can be exemplified. Among them, a Fe₄₀CO₆₀ alloy through a Fe₆₀CO₄₀ alloy may be employed in view of the above-described requirements.

In the case that the top pinned layer 143 is made of the magnetic layer with bcc-structure easily exhibiting the high MR variation ratio, the thickness of the top pinned layer 143 is preferably set to 1.5 nm or over so as to maintain the bcc-structure thereof stably. Since the spin valve film is made mainly of a metallic material with fcc-structure or fct-structure, only the top pinned layer 143 may have the bcc-structure. In this point of view, too thin top pinned layer 143 cannot maintain the bcc-structure thereof stably so as not to obtain the high MR variation ratio.

Herein, the top pinned layer 143 is made of the Fe₅₀CO₅₀ layers and the extremely thin Cu layers. The total thickness of the Fe_{50Co50} layers is 3 nm and each Cu layer is formed on the corresponding Fe_{50Co50} layer with a thickness of 1 nm. The thickness of the Cu layer is 0.25 nm and the total thickness of the top pinned layer 143 is 3.5 nm.

It is desired that the thickness of the top pinned layer 143 is set to 5 nm or below so as to generate a large pinning (fixing) magnetic field. In view of the large pinning (fixing) magnetic field and the stability of the bcc-structure in the top pinned layer 143, the thickness of the top pinned layer 143 is preferably set within 2 to 4 nm.

The top pinned layer 143 may be made of a CO₉₀Fe₁₀ alloy with fcc-structure or a Co alloy with hcp-structure which used to be widely employed for a conventional magneto-resistance effect element, instead of the magnetic material with the bcc-structure.

The top pinned layer 143 can be made of a single element such as Co, Fe, Ni or an alloy containing at least one of Co, Fe, Ni. In view of the high MR variation ratio of the top pinned layer 143, the FeCo alloy with the bcc-structure, the Co alloy containing Co element of 50% or over and the Ni alloy containing Ni element of 50% or over are in turn preferable.

In this embodiment, the top pinned layer 143 is made of the magnetic layers (FeCo layers) and the non magnetic layers (extremely thin Cu layers). In this case, the top pinned layer 143 can enhance the spin dependent scattering effect which is also called as a “spin dependent bulk scattering effect”, originated from the extremely thin Cu layers.

The spin dependent bulk scattering effect is utilized in pairs for the spin dependent interface scattering effect. The spin dependent bulk scattering effect means the occurrence of an MR effect in a magnetic layer and the spin dependent interface scattering effect means the occurrence of an MR effect at an interface between a spacer layer and a magnetic layer.

Hereinafter, the enhancement of the bulk scattering effect of the stacking structure of the magnetic layer and the non magnetic layer will be described. With the CCP-CPP element, since a current is confined in the vicinity of the spacer layer 16, the resistance in the vicinity of the spacer layer 16 contributes the total resistance of the magneto-resistance effect element. Namely, the resistance at the interface between the spacer layer 16 and the magnetic layers (pinned layer 14 and the free layer 18) contributes largely to the magneto-resistance effect element. That means the contribution of the spin dependent interface scattering effect becomes large and important in the CCP-CPP element. The selection of magnetic material located at the interface for the CCP-NOL layer 16 is important in comparison with a conventional CPP element. In this point of view, the pinned layer 143 is made of the FeCo alloy with the bcc-structure exhibiting the large spin dependent interface scattering effect as described above.

However, it may be that the spin dependent bulk scattering effect should be considered so as to develop the MR variation ratio. In view of the development of the spin dependent bulk scattering effect, the thickness of the thin Cu layer is set preferably within 0.1 to 1 nm, more preferably within 0.2 to 0.5 nm. Too thin Cu layer cannot develop the spin dependent bulk scattering effect sufficiently. Too thick Cu layer may reduce the spin dependent bulk scattering effect and weaken the magnetic coupling between the magnetic layers via the non magnetic Cu layer, which the magnetic layers sandwiches the non magnetic Cu layer, thereby deteriorating the property of the pinned layer 14. In a preferred embodiment, in this point of view, the thickness of the non-magnetic Cu layer is set to 0.25 nm.

The non-magnetic layer sandwiched by the magnetic layers may be made of Hf, Zr, Ti instead of Cu. In the case that the pinned layer 14 contains the non-magnetic layer(s), the thickness of the one magnetic layer such as a FeCo layer which is separated by the non-magnetic layer is set preferably within 0.5 to 2 nm, more preferably within 1 to 1.5 nm.

In the above embodiment, the top pinned layer 143 is constituted of the alternately stacking structure of FeCo layer and Cu layer, but may be made of an alloyed layer of FeCo and Cu. The composition of the resultant FeCoCu alloy may be set to ((Fe_{X}CO_{100-X})_{100-Y}Cu_{Y:} X=30 to 100%, Y=3 to 15%), but set to another composition range. The third element to be added to the main composition of FeCo may be selected from Hf, Zr, Ti, Al instead of Cu.

The top pinned layer 143 may be also made of a single element such as Co, Fe, Ni or an alloy thereof. In a simplified embodiment, the top pinned layer 143 may be made of an Fe₉₀Co₁₀ layer with a thickness of 2 to 4 nm, as occasion demands, containing a third additive element.

Then, the film structure in the extended spacer layer will be described. The bottom metallic layer 15 is a remained layer used as supplier for the formation of the conductive portion 162 in the process described later. It is not required that the bottom metallic layer 15 remains after the process.

The spacer layer (CCP-NOL) 16 includes the insulating layer 161 and the conductive portion 162. As already mentioned, the spacer layer 16, the bottom metallic layer 15 and the top metallic layer 17 are treated as the extended spacer layer 16s.

The insulating layer 161 is made of oxide. For example, the insulating layer 161 may be made of an Al₂O₃ amorphous structure or an MgO crystalline structure. In order to exhibit the inherent function of the spacer layer, the thickness of the insulating layer 161 is set preferably within 1 to 5 nm, more preferably within 1.5 to 4.5 nm.

The insulating layer 161 may be made of a typical insulating material such as Al₂O₃-based material, as occasion demands, containing a third additive element such as Ti, Hf, Mg, Zr, V, Mo, Si, Cr, Nb, Ta, W, B, C, V. The content of the additive element may be appropriately controlled within 0 to 50%. In a preferred embodiment, the insulating layer 161 is made of an Al₂O₃ layer with a thickness of about 2 nm.

The insulating layer 161 may be made of Ti oxide, Hf oxide, Mg oxide, Zr oxide, Cr oxide, Ta oxide, Nb oxide, Mo oxide, Si oxide or V oxide instead of the Al oxide such as the Al₂O₃. In the use of another oxide except the Al oxide, a third additive element such as Ti, Hf, Mg, Zr, V, Mo, Si, Cr, Nb, Ta, W, B, C, V may be added to the oxide as occasion demands. The content of the additive element may be appropriately controlled within 0 to 50%.

The insulating layer 161 may be also made of a nitride or an oxynitride containing, as a base material, Al, Si, Hf, Ti, Mg, Zr, V, Mo, Nb, Ta, W, B, C only if the insulating layer 161 can exhibit the inherent insulating function.

The conductive portion 162 functions as a path to flow a current in the direction perpendicular to the film surface of the spacer layer 16 and then, confining the current. The conductive portion 162 (CCP) may be made of Au, Ag, Ni, Co, Fe or an alloy containing at least one from the listed elements instead of Cu. In a preferred embodiment, the conductive portion 162 is made of a Cu alloy. The conductive portion 162 may be made of an alloy layer of CuNi, CuCo or CuFe. Herein, the content of Cu in the alloy is set preferably to 50% or over in view of the enhancement of the MR variation ratio and the reduction of the interlayer coupling field, Hin between the pinned layer 14 and the free layer 18.

The top metallic layer 17 is a portion of the extended spacer layer 16s. It functions as a barrier layer protecting the oxidization of the free layer 18 to be formed thereon through the contact with the oxide of the CCP-NOL layer 16 so that the crystal quality of the free layer 18 cannot be deteriorated. For example, when the insulating layer 161 is made of an amorphous material (e.g., Al₂O₃), the crystal quality of a metallic layer to be formed on the layer 161 may be deteriorated, but when a layer (e.g., Cu layer) to develop the crystal quality of fcc-structure is provided (under the condition that the thickness of the metallic layer is set to 1 nm or below), the crystal quality of the free layer 18 can be remarkably improved.

It is not always required to provide the top metallic layer 17 dependent on the kind of material in the extreme thin oxide layer 16 and/or the free layer 18. Moreover, If the annealing condition is optimized and the appropriate selection of the materials of the insulating layer 161 of the thin oxide layer 16 and the free layer 18 is performed, the deterioration of the crystal quality of the free layer 18 can be prevented, thereby omitting the metallic layer 17 of the spacer layer 16.

In view of the manufacturing yield of the magneto-resistance effect element, it is desired to form the top metallic layer 17 on the spacer layer 16. In a preferred embodiment, the top metallic layer 17 can be made of a Cu layer with a thickness of 0.5 nm.

The top metallic layer 17 may be made of Au, Ag, Ru or the like instead of Cu. Moreover, it is desired that the top metallic layer 17 is made of the same material as the material of the conductive portion 162 of the spacer layer 16. If the top metallic layer 17 is made of a material different from the material of the conductive portion 162, the interface resistance between the layer 17 and the path 162 is increased, but if the top metallic layer 17 is made of the same material as the material of the conductive portion 162, the interface resistance between the layer 17 and the path 162 is not increased.

The thickness of the top metallic layer 17 is set preferably within 0 to 1 nm, more preferably within 0.1 to 0.5 nm. Too thick top metallic layer 17 may extend the current confined through the spacer layer 16 thereat, resulting in the decrease of the MR variation ratio due to the insufficient current confinement.

The free layer 18 is a ferromagnetic layer of which the direction of magnetization is varied commensurate with the external magnetic field. For example, the free layer 18 is made of a double-layered structure of CO₉₀Fe₁₀ 1 nm/Ni₈₃Fe₁₇ 3.5 nm. In this case, in order to realize the high MR variation ratio, the selection of magnetic material of the free layer 18 in the vicinity of the spacer 16, that is, at the interface therebetween is important. In this case, it is desired that the CO₉₀Fe₁₀ layer is formed at the interface between the free layer 18 and the spacer layer 16. The free layer 18 may be made of a single CO₉₀Fe₁₀ layer with a thickness of 4 nm without a NiFe layer or a triple-layered structure of CoFe/NiFe/CoFe.

Then, the free layer 18 is made of an alternately stacking structure of CoFe layers or Fe layers with a thickness of 1 to 2 nm and extremely thin Cu layers with a thickness of 0.1 to 0.8 nm.

In the case that the spacer layer 16 is made of the Cu layer, it is desired that the FeCo layer with bcc-structure is employed as the interface material thereof for the spacer layer 16 so as to enhance the MR variation ratio in the same manner as the pinned layer 14. Moreover, in order to improve the stability in the bcc structure, a thickness not smaller than 1 nm is preferable and a thickness not smaller than 1.5 nm is more preferable. The increase of the thickness in bcc structure brings about an increase of coercivity and magnetostriction. Therefore, the thick bcc structure is difficult to be used for the free layer. To solve this problem, it is available to adjust the composition and film thickness of laminating NiFe alloy. In a preferred embodiment, a CO₆₀Fe₄₀ 2 nm/Ni₉₅Fe₅ 3.5 nm may be employed.

The cap layer 19 functions as protecting the spin valve film. The cap layer 19 may be made of a plurality of metallic layers, e.g., a double-layered structure of Cu 1 nm/Ru 10 nm. The layered turn of the Cu layer and the Ru layer may be switched so that the Ru layer is located in the side of the free layer 18. In this case, the thickness of the Ru layer is set within 0.5 to 2 nm. The exemplified structure is particularly desired for the free layer 19 of NiFe because the magnetostriction of the interface mixing layer formed between the free layer 18 and the cap layer 19 can be lowered due to the non-solution between Ru and Ni.

When the cap layer 19 is made of the Cu/Ru structure or the Ru/Cu structure, the thickness of the Cu layer is set within 0.5 to 10 nm and the thickness of the Ru layer is set smaller, e.g., within 0.5 to 5 nm due to the large specific resistance.

The cap layer 19 may be made of another metallic layer instead of the Cu layer and/or the Ru layer. The structure of the cap layer 19 is not limited only if the cap layer 19 can protect the spin valve film. If the protective function of the cap layer 19 can be exhibited, the cap layer 19 may be made of still another metal. Attention should be paid to the cap layer because the kind of material of the cap layer may change the MR variation ratio and the long reliability. In view of the stable MR variation ratio and long reliability, the Cu layer and/or the Ru layer is preferable for the cap layer.

The top electrode 20 functions as flowing a current through the spin valve film in the direction perpendicular to the film surface of the spin valve film. The intended current can be flowed through the spin valve film in the direction perpendicular to the film surface by applying a voltage between the top electrode 20 and the bottom electrode 11. The top electrode 20 may be made of a material with smaller resistance (e.g., Cu, Au, NiFe or the like).

The method for manufacturing a magneto-resistance effect element according to this embodiment can be applied to any one of the magneto-resistance effect elements having such a configuration.

Next, the third step (Step S130) in the method for manufacturing a magneto-resistance effect element according to this embodiment, namely, the specific example of the second treatment using light rare gas will be described.

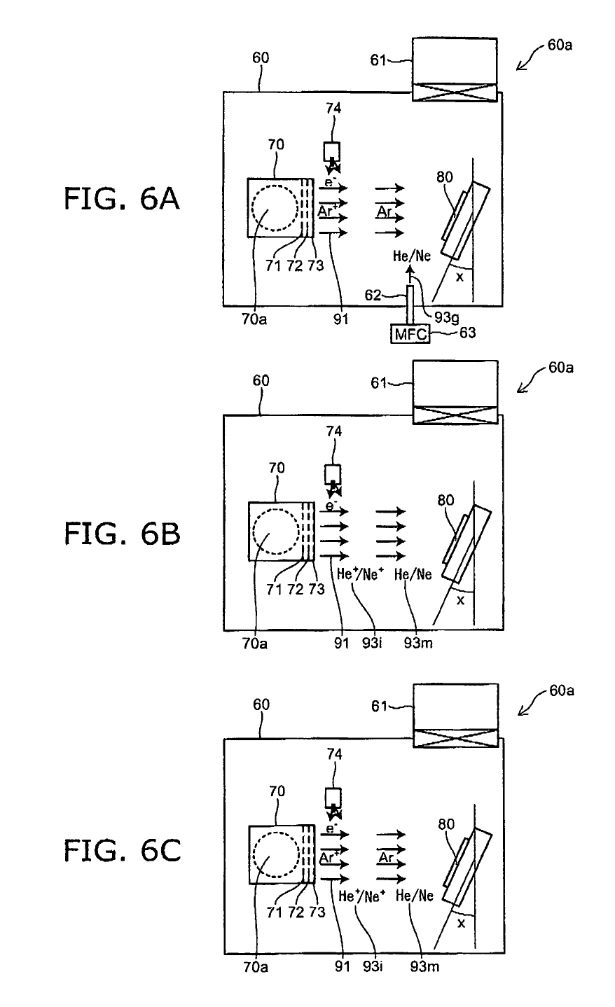

FIGS. 6A to 6C are schematic views illustrating configurations of parts in the method for manufacturing the magneto-resistance effect element according to the first embodiment of this invention.

That is, these figures illustrate three configurations of treatment apparatuses that can be used for the second treatment in the method for manufacturing a magneto-resistance effect element according to this embodiment.

FIG. 6A is a configuration in which exposure to at least one of helium gas and neon gas while irradiating ion beam or plasma of argon which is heavier rare gas than helium and neon.

As shown in FIG. 6A, the treatment apparatus 60a has a vacuum chamber 60 connected to a vacuum pump 61, and inside of the vacuum chamber 60 is made to be high vacuum. In the vacuum chamber 60, the object to be treated 80p (in this case, the laminated structure of the layer 14a including the film to be pinned layer 14 and the first metallic film 16a and the second metallic film 16b that are submitted to the first treatment) is placed. And, in the vacuum chamber 60, a plasma 70a generated from an ion source 70 is accelerated by grids 71, 72 and 73. In this example, Ar ion is used, and thereby Ar ion beam 91 is generated. In this case, neutralization is performed by a neutralizer 74. On the other hand, a helium gas 93g controlled by mass flow controller (MFC) 63 is introduced through a supply pipe 62 into the vacuum chamber 60. And, in an atmosphere of the helium gas 93g, the Ar ion beam 91 is irradiated to the object to be treated 80. In the above case, Ar plasma may be irradiated to the object to be treated 80 instead of the Ar ion beam 91.

As described above, in the exposure to helium gas 93g, by irradiating ion beams or plasma of argon which is heavier rare gas than helium, helium radicals are generated in the helium gas 93g. Then, the object to be treated 80 is treated by using the helium radicals. Thereby, the reduction can be promoted by cutting oxygen bonds of the oxide in the conductive portion 162.

Moreover, at least one of helium gas and neon gas is ionized and ions of at least one of helium gas and neon gas are generated, and the ions can be irradiated to the object to be treated 80.

As shown in FIG. 6B, for example, the helium gas 93g is introduced into the ion source 70 and plasma-activated, and thereby, helium plasma (helium in high energy state) 93m can be obtained. To this helium plasma, voltage is applied and accelerated by the grids 71, 72, 73, and thereby, beam of helium ion 93i is taken out. The helium ion beam having charge is electrically neutralized by the neutralizer 74 and reaches the object to be treated 80. Since helium has high energy, it can cut bonds between metal and oxygen easily, thereby, efficiency of reduction of the conductive portion 162 is improved. This is because the reduction of the oxide is hard to be promoted by helium gas without energy but the reduction comes to be easily promoted by providing energy to helium gas by plasma-activation or ionization.

In this case, it is preferable that the flow rate of the helium gas 93g introduced into the ion source is from 1 sccm to 100 sccm inclusive. If lower than 1 sccm, the reduction of the oxide in the conductive portion 162 is insufficient, and if higher than 100 sccm, the reduction of the oxide of the second metallic film 16b to be the insulating layer 161 begins.

In this method, because the reduction efficiency is high, the appropriate flow rate is lower than that of the case of the exposure to the helium gas 93g described with respect to FIG. 6A. It is desirable that the voltage applied to the grids 71, 72 and 73 is from 0 V to 50 V inclusive. The case of 0 V is the state in which helium ion 93i getting out from the grids is utilized. In the case of RF plasma, the power is from 10 W to 1000 W inclusive. The reason why weak voltage or RF power is used as described above is to prevent CCP-NOL from being broken by reducing Al₂O₃ to be the insulating layer 161.

Furthermore, the helium ion 93i and ion of argon which is heavier rare gas than helium can be irradiated to the object to be treated 80 at the same time.

As shown in FIG. 6C, the helium ion 931 and Ar ion beam 91 based on heavy rare gas are irradiated to the object to be treated 80 at the same time, and thereby, the efficiency of reduction can be further improved.

In this case, it is preferable that the flow rate of the helium gas 93g introduced into the ion source is from 1 sccm to 100 sccm inclusive. If lower than 1 sccm, the reduction of the oxide in the conductive portion 162 is insufficient, and if higher than 100 sccm, the reduction of the oxide of the second metallic film 16b to be the insulating layer 161 begins.

Also, in this method, because the reduction efficiency is high, the appropriate flow amount is smaller than that of the case of the exposure to the helium gas 93g described with respect to FIG. 6A. It is desirable that the voltage applied to the grids 71, 72 and 73 is from 0 V to 50 V inclusive. The case of 0 V is the state in which helium ion 93i getting out from the grids is utilized. In the case of RF plasma, the power is from 10 W to 1000 W inclusive. The reason why weak voltage or RF power as described above is used is to prevent CCP-NOL from being broken by reducing Al₂O₃.

In the above-described second treatment using light rare gas, the treatment may be performed with heating the insulating layer 161 and the conductive portion 162. During heating the insulating layer 161 and the conductive portion 162, the exposure to the helium gas 93g or treatment of irradiation of various types of helium ion 93i and or helium plasma, which has been explained with respect to the FIGS. 6A to 6C. Thereby, the reduction efficiency is enhanced and the treatment can be more efficiently performed.

By the second treatment is performed with heating the first metallic film 16a and the second metallic film 16b, oxygen generated in the second treatment can also be removed. Furthermore, the crystallinity may be improved.

The same effect as heating can also be obtained by irradiating the ion beam or the plasma of argon which is heavier rare gas than helium and neon.

After performing Step S110 to Step S130, further the Step S120 (the first treatment of the second time) may be performed. Thereby, oxidation by the first treatment and reduction by the second treatment can be adjusted. Furthermore, after the first treatment of the second time, the second treatment of the second time may be performed. As described above, after the step S110 of film formation, the combination of Step S120 and Step S130 can be repeatedly performed. Thereby, the structure of the insulating layer 161 and the conductive portion 162 can be precisely controlled.

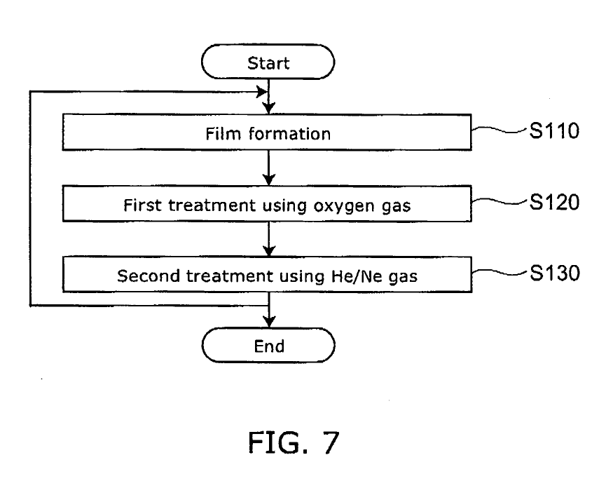

FIG. 7 is a flow chart illustrating another method for manufacturing a magneto-resistance effect element according to the first embodiment of this invention.

As shown in FIG. 7, in another method for manufacturing a magneto-resistance effect element according to the first embodiment of this invention, the first step (Step S110), the second step (Step S120), and the third step (Step S130), which have been explained with respect to FIG. 1, are repeated plural times and performed.

Hereinafter, the example of the case of two repeating times will be described.

Also in this case, the second step (Step S120) may include the PIT step (Step S120a illustrated in FIG. 3) and the IAO step (Step S120b illustrated in FIG. 3).

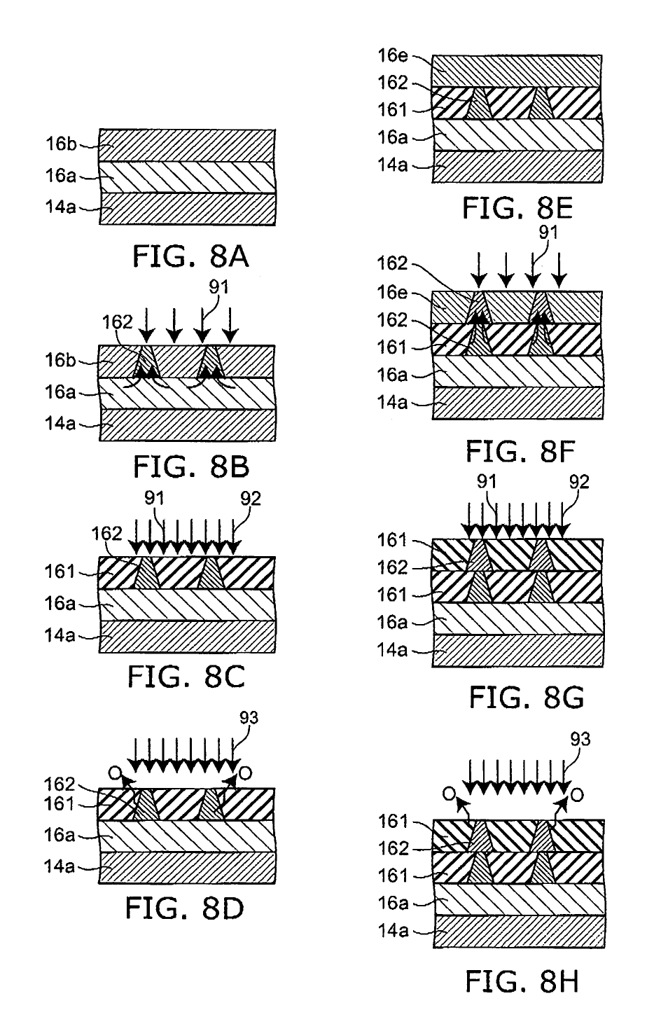

FIGS. 8A to 8H are schematic sectional views following step sequence illustrating another method for manufacturing a magneto-resistance effect element according to a first embodiment of this invention.

That is, FIG. 8A is a figure showing the first step, and Each of FIGS. 8B to 8H is a view showing the step following its previous step.

FIGS. 8A to 8D are the same as FIGS. 4A to 4D, and therefore, the explanation thereof will be omitted.

As shown in FIG. 8E, Step S110 of the second time is performed. That is, after Step S110 to Step S130 of the first time (formation of the film to be base material of the spacer layer 16, the first treatment using oxygen, the second treatment using light rare gas), the second metallic film 16e of the second layer is formed. The second metallic film 16e of the second layer is also, for example, Al. The second metallic film 16e of the second layer may be AlCu.

Then, Step S120 of the second time is performed.

That is, as shown in FIG. 8F, PIT by the Ar ion beam 91 is performed. Thereby, the conductive portion 162 formed by the Step S110 to Step S130 of the first time are further sucked up into the second metallic film 16e of the second layer and penetrates through the second metallic film 16e of the second layer.

And, as shown in FIG. 8G, the second metallic film 16e of the second layer is submitted to the oxidizing treatment by IAO that is the first treatment using oxygen (in this case, oxygen ion beam 92). Thereby, the second metallic film 16e of the second layer that is Al is oxidized to be Al₂O₃ to form the insulating layer 161.

Subsequently, Step S130 of the second time is performed.

That is, as shown in FIG. 8H, the above-described film is irradiated with the helium ion beam 93 for example, and CuO generated by oxidation of the first metallic film 16a is reduced to be Cu. Also in this case, a condition in which Al₂O₃ to be the insulating layer 161 is not substantially reduced and CuO is reduced is appropriately selected, and thereby, the resistance of the conductive portion 162 can be decreased with substantially no adverse effect to the insulating characteristics of the insulating layer 161.

As described above, according to the method for manufacturing a magneto-resistance effect element according to this embodiment, the oxide in the conductive portion 162 generated during forming the insulating layer 161 and the conductive portion 162 is reduced, and the amount of oxygen impurities in the conductive portion 162 is decreased. And, by performing plural times of formation of the film to be the spacer layer 16, the film thickness of each of the formed films becomes thin, and thereby, the stress in the film can be relaxed. Moreover, for each of the thin films, for example, PIT and IAO (the first treatment), and the second treatment are performed, and therefore, because each of the thin films is submitted to these treatments, the structure of the film is stabilized and the film becomes dense. Furthermore, these treatments are for activating the surface and the adhesive force of the film is improved and the reliability of the magneto-resistance effect element is improved.

Also, when a thick film as the spacer layer 16 is required, the formation of the film is performed plural times, and each of the films is submitted to the above-described treatment, and thereby, with maintaining the performance, the film thickness of the spacer layer 16 can be increased.

Thereby, the CCP-CPP type magneto-resistance effect element with high reliability having high MR variation ratio can be obtained.

### Second Embodiment

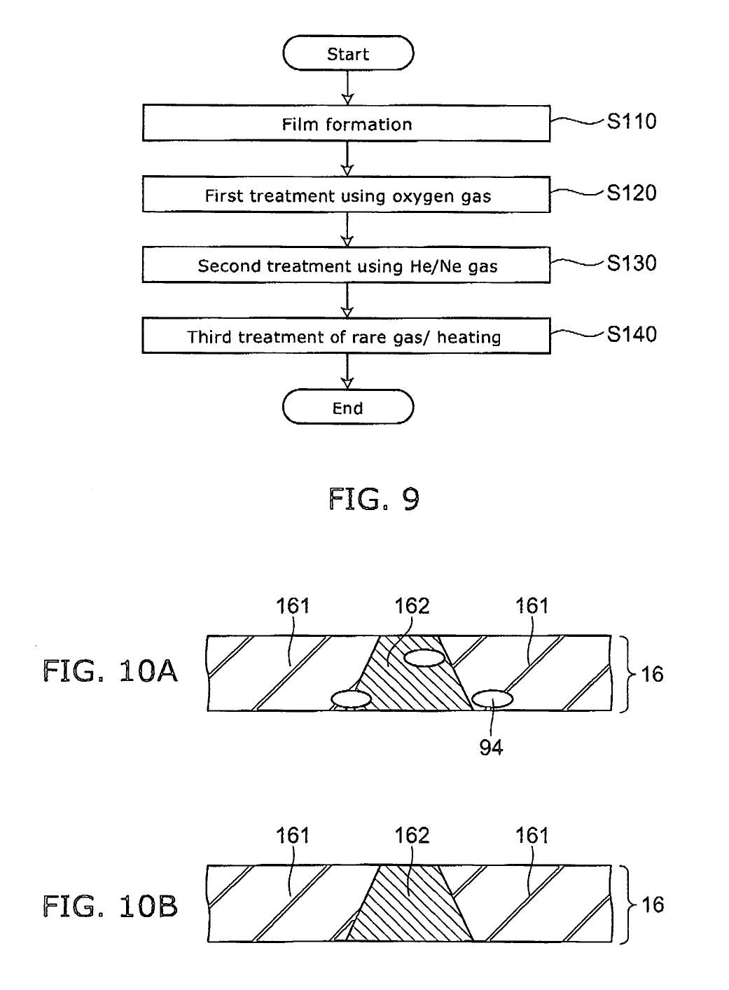

FIG. 9 is a flow chart illustrating a method for manufacturing a magneto-resistance effect element according to a second embodiment of this invention.

As shown in FIG. 9, in the method for manufacturing a magneto-resistance effect element according to a second embodiment of this invention, after the first step (Step S110), the second step (Step S120) and the third step (Step S130), which are explained with respect to FIG. 1, further a fourth step (Step S140) is carried out.

Also in this step, the second step (Step S120) may include the PIT step (Step S120a illustrated in FIG. 3) and the IAO step (Step S120b illustrated in FIG. 3).

In the fourth step, the film submitted to the second treatment is submitted to the third treatment of at least any one of irradiation of ion of argon which is heavier rare gas than helium and neon, irradiation of argon plasma, and heating.

As the third treatment, the insulating layer 161 and the conductive portion 162 are submitted to, for example, irradiation of Ar ion beam or irradiation of Ar plasma. Or, as the third treatment, the insulating layer 161 and the conductive portion 162 are heated. Or, as the third treatment, during heating the insulating layer 161 and the conductive portion 162, for example, irradiation of Ar ion beam or irradiation of Ar plasma is performed.

Thereby, oxygen (O) generated by the second treatment can be removed.

FIGS. 10A and 10B are schematic sectional views illustrating the effect of the method for manufacturing a magneto-resistance effect element according to the second embodiment of this invention.

That is, FIG. 10A illustrates the state after the second treatment, and FIG. 10B illustrates the state after the third treatment.

As shown in FIG. 10A, after the second treatment, in the insulating layer 161 and the conductive portion 162, oxygen 94 generated by the second treatment occasionally remains. In this case, the residual oxygen 94 diffuses in the anneal step after finishing stacking all of the films and can oxidize the surrounding metallic films. The conductive portion 162 reduced in the second treatment may be reoxidized by the residual oxygen 94 in the anneal step. For preventing this, the following third treatment is performed to remove oxygen 94.

That is, as shown in FIG. 10B, by performing the third treatment of at least any one of irradiation of ion of argon which is heavier gas than helium and neon and irradiation of argon plasma and heating, the residual oxygen 94 can be removed. The removed oxygen 94 from the insulating layer 161 and the conductive portion 162 is exhausted through the space of the treatment chamber to the outside of the treatment chamber.

Thus, by removing the residual oxygen 94 from the insulating layer 161 and the conductive portion 162, the electric resistance characteristic of the insulating layer 161 and the conductive portion 162 is stabilized. Moreover, for example, film-formation of the second magnetic layer or the like successively performed can be stabilized and the adhesive forces of the stacked films to one another can be improved.

By the third treatment of at least any one of irradiation of ion of argon which is heavier than helium and neon and irradiation of argon plasma and heating, for example, crystallinity of the conductive portion 162 is improved and the resistance thereof is further decreased. Thereby, the MR variation ratio can be further improved.

As described above, for example, by heating the insulating layer 161 and the conductive portion 162 in the second treatment, the third treatment can be omitted. Also, for example, even when the insulating layer 161 and the conductive portion 162 are heated in the second treatment, if the removal of oxygen 94 is insufficient, the third treatment may be performed to promote the removal of oxygen 94.

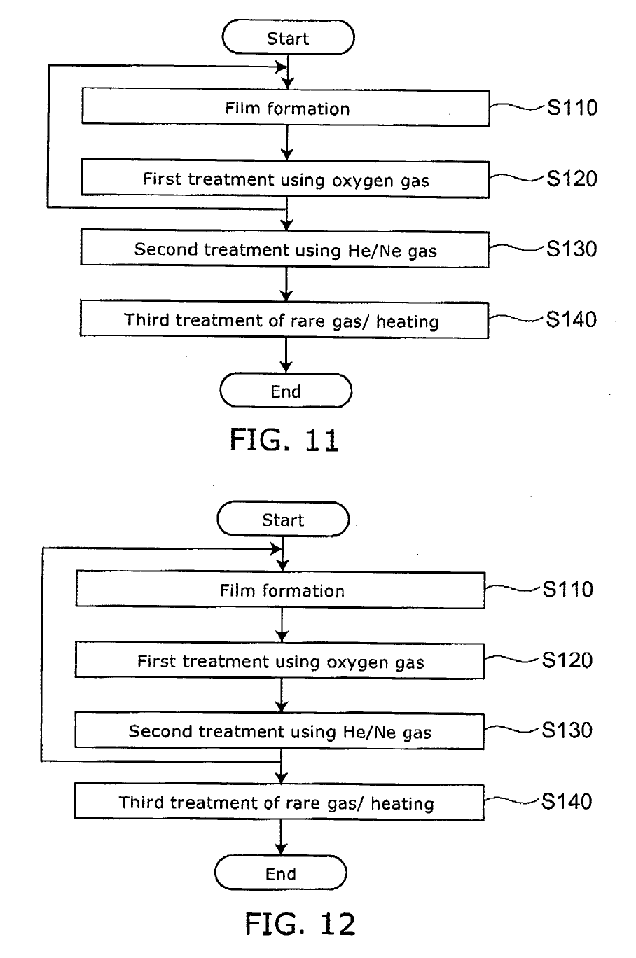

FIG. 11 is a flow chart illustrating another method for manufacturing a magneto-resistance effect element according to the second embodiment of this invention.

As shown in FIG. 11, in this specific example, Step S110 to Step S120 are repeated. That is, a spacer layer 16 having a plurality of laminated structures is formed and then the second treatment and third treatment is performed. As described above, in the method for manufacturing a magneto-resistance effect element according to this embodiment, Step S110 to Step S120 may be repeated plural times and performed.

Also in this case, the second step (Step S120) may include the PIT step (Step S120a illustrated in FIG. 3) and the IAO step (Step S120b illustrated in FIG. 3).

FIG. 12 is a flow chart illustrating another method for manufacturing a magneto-resistance effect element according to the second embodiment of this invention.

As shown in FIG. 12, in the method for manufacturing another magneto-resistance effect element according to the second embodiment of this invention, the spacer layer 16 having two-layer structure by repeating Step S110 to Step S130, which has been described by using FIGS. 7 and 8, is submitted to the third treatment. By repeating the oxidation treatment and the reduction treatment, the second metallic film 16b, which is easy to be oxidized, is more oxidized, and the first metallic film 16a and the conductive portion 162, which are easy to be reduced, are more reduced. That is, the difference of oxidation energies between the materials can be emphasized and utilized. Thereby, the magneto-resistance effect element having a high reliability and a high MR variation ratio can be obtained.

Also in this case, the second step (Step S120) may include the PIT step (Step S120a illustrated FIG. 3) and the IAO step (Step S120b illustrated FIG. 3).

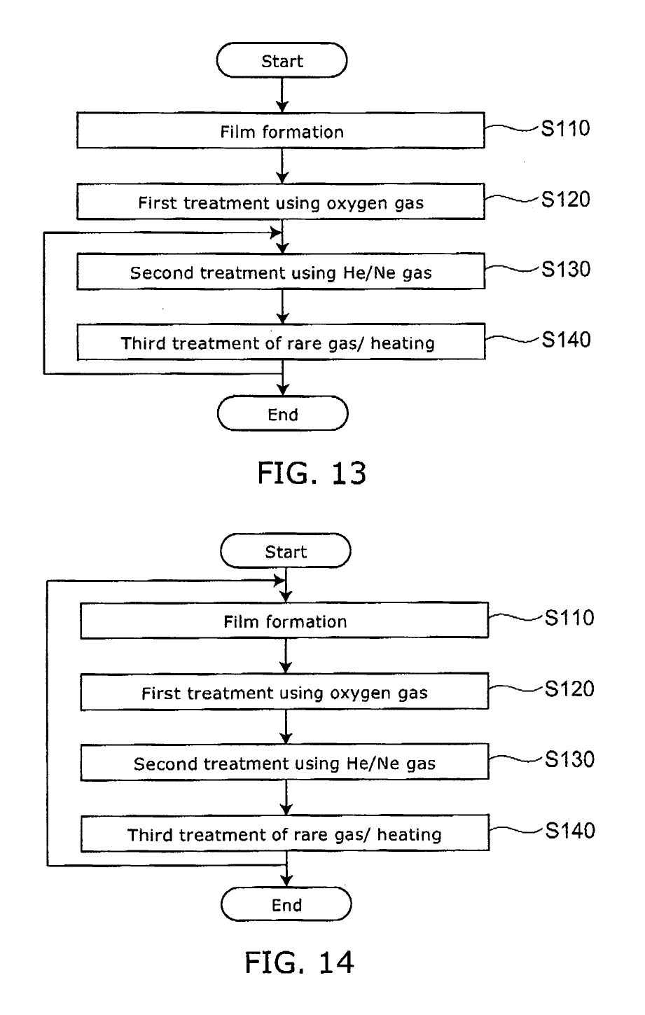

FIG. 13 is a flow chart illustrating another method for manufacturing a magneto-resistance effect element according to the second embodiment of this invention.

As shown in FIG. 13, in another method for manufacturing the magneto-resistance effect element according to the second embodiment of this invention, Step S130 to Step S140 are repeated. This is for removing extra oxygen 94 before a large amount of the H₂O is accumulated, by repeating the second step (reduction treatment) and the third treatment (subsequent removal of oxygen 94). By performing the third treatment before the large amount is accumulated, the third treatment can have a weak condition. Specifically, when the third treatment is Ar plasma irradiation, if irradiation is repeated twice, RF power is sufficient to be half of that of the case of one-time irradiation. Or, the time may be about half. Anyway, the damage provided to the insulating layer 161 and the conductive portion 162 in the third treatment is suppressed, and the insulating layer 161 with a higher dense and the conductive portion 162 with a higher purity are formed and the MR variation ratio is improved.

Also in this case, the second step (Step S120) may include the PIT step (Step S120a illustrated FIG. 3) and the IAO step (Step S120b illustrated FIG. 3).

FIG. 14 is a flow chart illustrating another method for manufacturing a magneto-resistance effect element according to the second embodiment of this invention.

As shown in FIG. 14, in another method for manufacturing a magneto-resistance effect element according to the second embodiment of this invention, Step S110 to Step S140 are repeated. That is, the spacer layer 16 having a plurality of structures is formed, and the third treatment is performed in each of the treatments.

Also in this case, the second step (Step S120) may include the PIT step (Step S120a illustrated FIG. 3) and the IAO step (Step S120b illustrated FIG. 3).

The effects of the second treatment and the third treatment become weaker as the position is deeper in the direction of the film thickness. That is, when the spacer layer 16 is formed by repeating Step S110 to Step S120 three times, CuO reduction and oxygen 94 removal can be realized and crystallinity improvement of the conductive portion 162 can be expected in the upper portion (shallow portion) of the spacer layer 16, but in the bottom portion (deep portion) of the spacer layer 16, occasionally, the degree of CuO reduction is relatively low and the residual amount of oxygen 94 is relatively large and the crystallinity is also relatively degraded. Accordingly, by repeating Step S110 to Step S140, the characteristics are improved. That is, the rather thin insulating layer 161 and conductive portion 162 are submitted to the second treatment (Step S130) and the third treatment (Step S140), and thereby, CuO is sufficiently reduced and oxygen 94 is removed, and the crystallinity of the conductive portion 162 is improved. Then, moreover, the rather thin insulating layer 161 and conductive portion 162 are formed and submitted to the second treatment (Step S130) and the third treatment (Step S140), and thereby, CuO is sufficiently reduced and oxygen 94 is removed and the crystallinity of the conductive portion 162 is improved.

As described above, according to the method for manufacturing a magneto-resistance effect element of this specific example, the spacer layer 16 is formed plural times to ensure high reliability, and the residue of oxygen generated in this process in the conductive portion 162 is effectively suppressed, and furthermore, the residual oxygen 94 is removed and the crystallinity is also improved, and the magneto-resistance effect element having high MR variation ratio can be obtained.

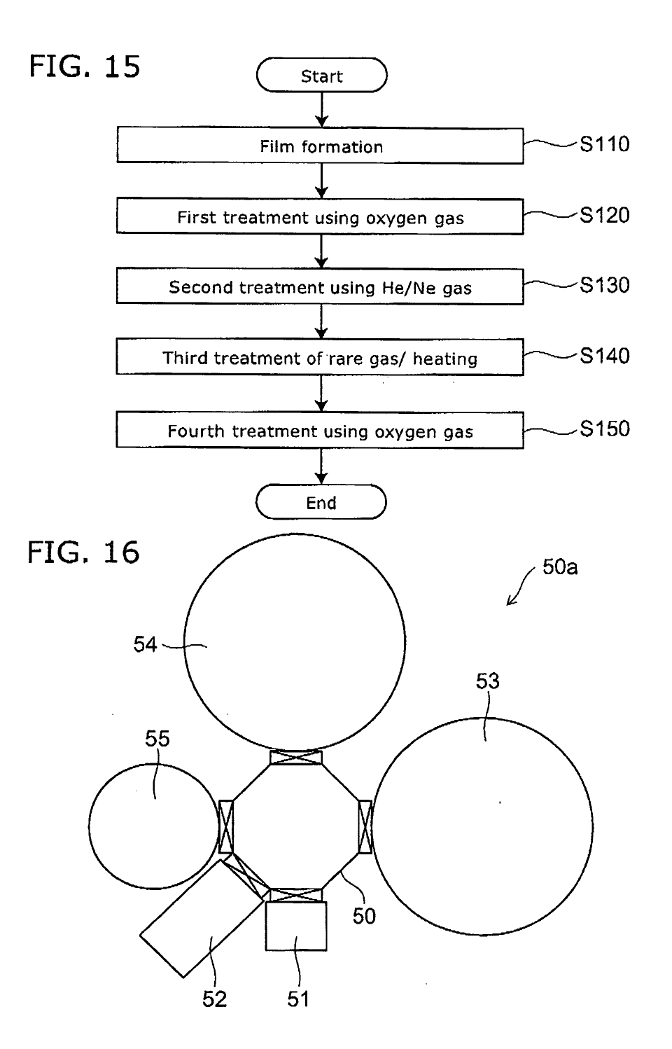

FIG. 15 is a flow chart illustrating another method for manufacturing a magneto-resistance effect element according to the second embodiment of this invention.

As shown in FIG. 15, another method for manufacturing a magneto-resistance effect element according to the second embodiment of this invention, after the first step (Step S110), the second step (Step S120), the third step (Step S130) and fourth step (Step S140), which are explained with respect to FIG. 10, further a fifth step (Step S150) is carried out.

In some cases, after the fourth step, the insulator part of the spacer layer 16 (CCP-NOL layer) may be slightly reduced and the voltage-robustness may be decreased. By performing the fifth step (Step S150), an amount of oxygen in the insulator part of the spacer layer 16 is increased again and the voltage-robustness can be recovered. The oxidation condition of the fifth step (Step S150) may be selected substantially not to oxidize the metal which forms mainly the spacer layer 16.

In the fifth step, the film submitted to the third treatment is submitted to the fourth treatment of at least using a gas including at least one of oxygen molecules, oxygen atoms, oxygen ions, oxygen plasma and oxygen radicals to the film, the film submitted to the third treatment. In the fourth treatment, the film is oxidized.

Thus, the method further includes performing a fourth treatment using a gas including at least one of oxygen molecules, oxygen atoms, oxygen ions, oxygen plasma and oxygen radicals to the film, the film submitted to the third treatment.

In the method for manufacturing a magneto-resistance effect element according to the embodiments of this invention, an apparatus described below can be used.

FIG. 16 is a schematic view illustrating a configuration of a manufacturing apparatus used for the method for manufacturing a magneto-resistance effect element according to the embodiments of this invention.

As shown in FIG. 16, in the manufacturing apparatus 50a used for the method for manufacturing a magneto-resistance effect element according to the embodiments of this invention, the transfer chamber (TC) 50 is disposed at the center of the apparatus such that the first chamber (the load lock chamber) 51, the second chamber 52, the third chamber 53, the forth chamber and the fifth chamber 55 are disposed so as to be connected with the transfer chamber 50 via the gate valves, respectively. In this manufacturing apparatus 50a, forming films and various treatments are performed. In the apparatus, the substrate on which various films are to be formed is transferred from one chamber to another chamber under the vacuum condition via the corresponding gate valve. Therefore, the surface of the substrate can be maintained clean.

In the second chamber 52, for example, the exposure to the helium gas 93g (including helium ions 93i and helium plasma), helium radicals and helium plasma and the irradiation of helium ion 93i and helium plasma are performed. That is, the second treatment is preformed. Moreover, the irradiation of ions of argon which is heavier than helium and neon and argon plasma may be performed. That is, the third treatment is performed. The second chamber 52 may includes a heating stage and the heating treatment in the second treatment and the third treatment can be performed.

In the third chamber 53, a pre-cleaning and the treatment with rare gas plasma are performed. In other words, the PIT treatment is performed, for example.

In the forth chamber 54, metallic films are formed.

In the fifth chamber 55, oxide layers are formed.

The forth chambers 54 may include a plurality of targets (five to ten targets) which is called as a multi-structured target. As the film forming means, a sputtering method such as a DC magnetron sputtering or an RF magnetron sputtering, an ion beam sputtering, a vacuum deposition, a CVD (Chemical Vapor Deposition) or an MBE (Molecular Beam Epitaxy) can be employed.

When a Strengthen Adhesion Treatment (SAT) is performed for the spacer layer 16, the SAT is performed in a chamber having RF plasma mechanism, ion beam mechanism or heating mechanism. More specifically, the forth chamber 54 or the second chamber 52 having a RF plasma mechanism. Since the RF plasma mechanism has a simplified mechanism, by using the forth chambers 54, both of the metallic film formation and the SAT can be performed.

Herein, it is not desired that the SAT is performed in the fifth chamber 55. In this case, the oxygen gas absorbed onto the inner wall of the oxidation chamber is released to contaminate the free layer 18 so that the free layer 18 may be deteriorated. In a chamber as the forth chamber 54, since the oxygen gas is not absorbed onto the inner wall of the chamber because the oxygen gas is not used at the film-forming process, the vacuum condition of the chamber can be easily maintained.

The pressure in the above-described vacuum chamber is in the order of 10⁻⁹ Torr, and the allowable pressure range is the order of 5×10⁻⁸ Torr or below.

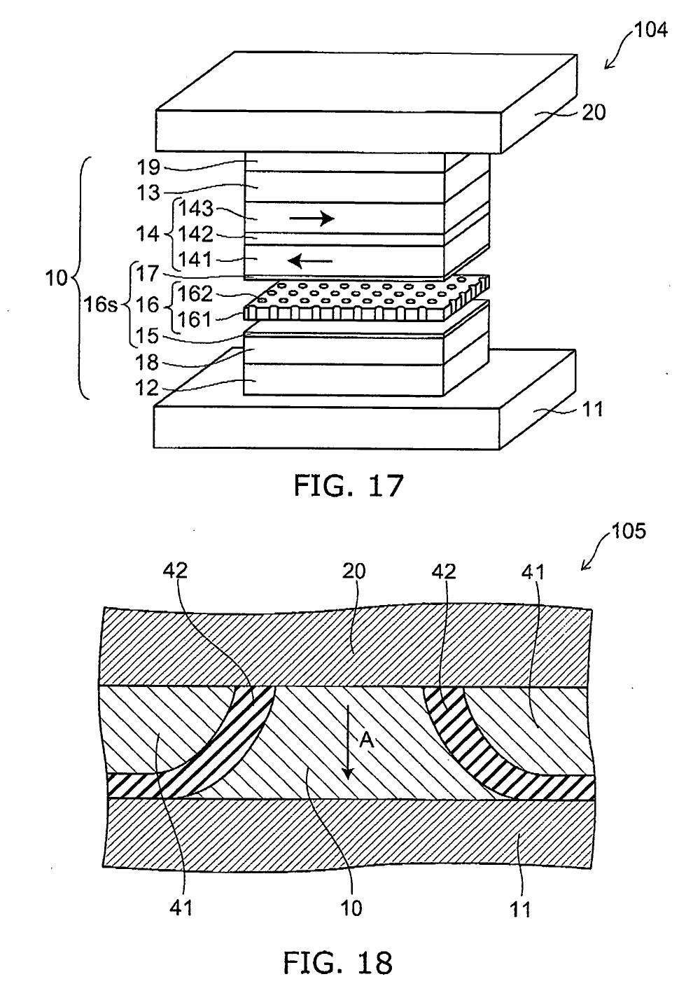

FIG. 17 is a schematic perspective view illustrating a configuration of another magneto-resistance effect element to which the method for manufacturing a magneto-resistance effect element according to the embodiments of this invention is applied.

As shown in FIG. 17, another magneto-resistance effect element 104 to which the method for manufacturing a magneto-resistance effect element according to the embodiments of this invention is applied, is a top-type CCP-CPP element in which the pinned layer 14 is located above the free layer 18. The method for manufacturing a magneto-resistance effect element according to the first and the second embodiments can also be applied to the top-type CCP-CPP element, as well as the bottom-type CCP-CPP (such as magneto-resistance effect element 101) in which the pinned layer 14 is located below the free layer 18, and the same effect can be obtained.

### Third Embodiment

The magneto-resistance effect element 105 (not shown) according to a fourth embodiment of this invention is any one of the magneto-resistance effect elements (CCP elements) produced by the method for manufacturing a magneto-resistance effect element of the first and the second embodiments. That is, the magneto-resistance effect element 105 includes the above-described magneto-resistance effect elements 101 and 104.

In the embodiment of the present invention, in view of high density recording, the element resistance RA is set preferably to 500 mΩ/μm² or below, more preferably to 300 mΩ/μm² or below. In the calculation of the element resistance RA, the effective area A in current flow of the spin valve film is multiplied to the resistance R of the CPP-CPP element. Herein, the element resistance R can be directly measured, but attention should be paid to the effective area A because the effective area A depends on the element structure.

If the whole area of the spin valve film is effectively sensed by current through patterning, the whole area of the spin valve film corresponds to the effective area A. In this case, the whole area of the spin valve film is set to 0.04 μm² or below in view of the appropriate element resistance, and to 0.02 μm² or below in view of the recording density of 300 Gbpsi or over.

If the area of the bottom electrode 11 or the top electrode 20 is set smaller than the whole area of the spin valve film, the area of the bottom electrode 11 or the top electrode 20 corresponds to the effective area A. If the area of the bottom electrode 11 is different from the area of the top electrode 20, the smaller area of either of the bottom electrode 11 or the top electrode 20 corresponds to the effective area A. As described above, the smaller area is set to 0.04 μm² or below in view of the appropriate element resistance

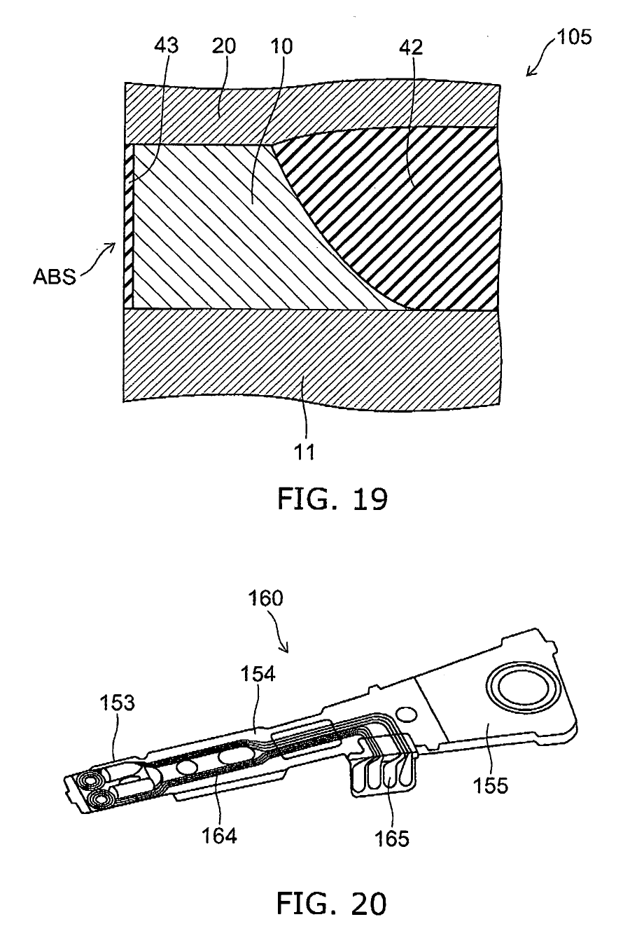

Referring to FIGS. 17 and 18 since the smallest area of the magneto-resistance effect film 10 in the magneto-resistance effect element 105 corresponds to the contacting area with the top electrode 20 as apparent from FIG. 18, the width of the smallest area can be considered as a track width Tw. Then, since the smallest area of the magneto-resistance effect films 10 in MR height direction also corresponds to the contacting area with the top electrode 20 as apparent from FIG. 28, the width of the smallest are can be considered as a height length D. In this case, the effective area A of the spin valve film can be calculated on the equation of A=Tw×D.

In the magneto-resistance effect element 105 according to the embodiments of this invention, the resistance R between the electrodes can be reduced to 100Ω or below, which corresponds to the resistance between the electrode pads in the reproducing head attached to the forefront of a head gimbal assembly (HGA, that is magnetic head assembly), for example.

In the magneto-resistance effect element 105 according to the embodiments of this invention, it is desired that the magneto-resistance effect element is structured in fcc (111) orientation when the pinned layer 14 or the free layer 18 has the fcc-structure. It is also desired that the magneto-resistance effect element is structured in bcc (100) orientation when the pinned layer 14 or the free layer 18 has the bcc-structure. It is also desired that the magneto-resistance effect element is structured in hcp (001) orientation when the pinned layer 14 or the free layer 18 has the hcp-structure.

The crystalline orientation of the magneto-resistance effect element 105 according to the embodiments of this invention, is preferably 4.0 degrees or below, more preferably 3.5 degrees or below and particularly 3.0 degree or below in view of the dispersion of orientation. The crystalline orientation can be measured from the FWHM of X-ray rocking curve obtained from the θ-2θ measurement in X-ray diffraction. The crystalline orientation can be also measured by the spot scattering angle originated from the nano-diffraction spots of the element cross section.

Depending on the kind of material of the antiferromagnetic film, since the lattice spacing of the antiferromagnetic film is different from the lattice spacing of the pinned layer 14/spacer layer 16/free layer 18, the dispersion in crystalline orientation can be obtained between the antiferromagnetic film and the pinned layer 14/spacer layer 16/free layer 18. For example, the lattice spacing of the PtMn antiferromagnetic layer is often different from the lattice spacing of the pinned layer 14/spacer layer 16/free layer 18. In this point of view, since the PtMn layer is formed thicker, the PtMn layer is suitable for the measurement in dispersion of the crystal orientation. With the pinned layer 14/spacer layer 16/free layer 18, the pinned layer 14 and the free layer 18 may have the respective different crystal structures of bcc-structure and fcc-structure. In this case, the dispersion angle in crystal orientation of the pinned layer 14 may be different from the dispersion angle in crystal orientation of the free layer 18.

FIGS. 17 and 18 are schematic cross sectional views illustrating application embodiments of the magneto-resistance effect element according to the embodiments of this invention.

More specifically, these figures illustrate the state where the magneto-resistance effect element 105 by using this embodiment is incorporated in a magnetic head. FIG. 18 is a cross sectional view showing the magneto-resistance effect element 105, taken on the surface almost parallel to the ABS (air bearing surface) opposite to a (not shown) magnetic recording medium. FIG. 19 is a cross sectional view showing the magneto-resistance effect element 105, taken on the surface perpendicular to the ABS.

The magnetic head shown in FIGS. 17 and 18 has a so-called hard abutted structure. The magneto-resistance effect element 105 is the CCP-CPP element as described above manufacture by any one of methods for manufacturing according to embodiments of this invention.

As shown in FIGS. 17 and 18, the bottom electrode 11 and the top electrode 20 are provided on the top surface and the bottom surface of the magneto-resistance effect film 10, respectively. The biasing magnetic applying films 41 and the insulating films 42 are formed at the both sides of the magneto-resistance effect film 10. As shown in FIG. 19, the protective layer 43 is formed on the ABS of the magneto-resistance effect film 10.

The sense current is flowed along the arrow A through the magneto-resistance effect film 10 between the bottom electrode 11 and the top electrode 20, that is, in the direction perpendicular to the film surface of the magneto-resistance effect film 10. Moreover, a given biasing magnetic field is applied to the magneto-resistance effect film 10 from the biasing magnetic field applying films 41 so as to render the domain structure of the free layer 18 of the film 10 a single domain structure through the control of the magnetic anisotropy of the free layer 18 and stabilize the magnetic domain structure of the free layer 18. In this case, the Barkhausen noise due to the shift of magnetic wall in the magneto-resistance effect film 10 can be prevented. Since the S/N ratio of the magneto-resistance effect film 10 is enhanced, the magnetic head including the magneto-resistance effect film 10 can realize the high sensitive magnetic reproduction.

### Fourth Embodiment

FIG. 20 is a schematic perspective view illustrating a configuration of magnetic head assembly according to the fourth embodiment of this invention.

As shown in FIG. 20, a magnetic head assembly (head gimbal assembly) 160 according to a fourth embodiment of this invention includes a suspension 154 in which the magneto-resistance effect element according to the embodiments of this invention is mounted at one end thereof and an actuator arm 155 connected to the other end of the suspension 154. Here, the magneto-resistance effect element is at least any one of the above-described magneto-resistance effect elements 101, 104, and 105.

That is, the head gimbal assembly 160 has the actuator arm 155, and the suspension 154 is connected to one end of the actuator arm 155. To the forefront of the suspension 154, a head slider having a magnetic head including the magneto-resistance effect element according to the embodiment of this invention is attached.

The suspension 154 has lead wires 164 for writing and reading of a signal, and the lead wire 164 and each of electrodes of the magnetic head incorporated into the head slider 153 are electrically connected. In the head gimbal assembly 160, an electrode pad 165 is provided.

The magnetic resistance head assembly according to this embodiment has a magnetic head including a magneto-resistance effect element manufactured by any one of the methods for manufacturing a magneto-resistance effect element according to the first and the second embodiments, and therefore, the magnetic head assembly having high MR variation ratio can be provided.

### Fifth Embodiment

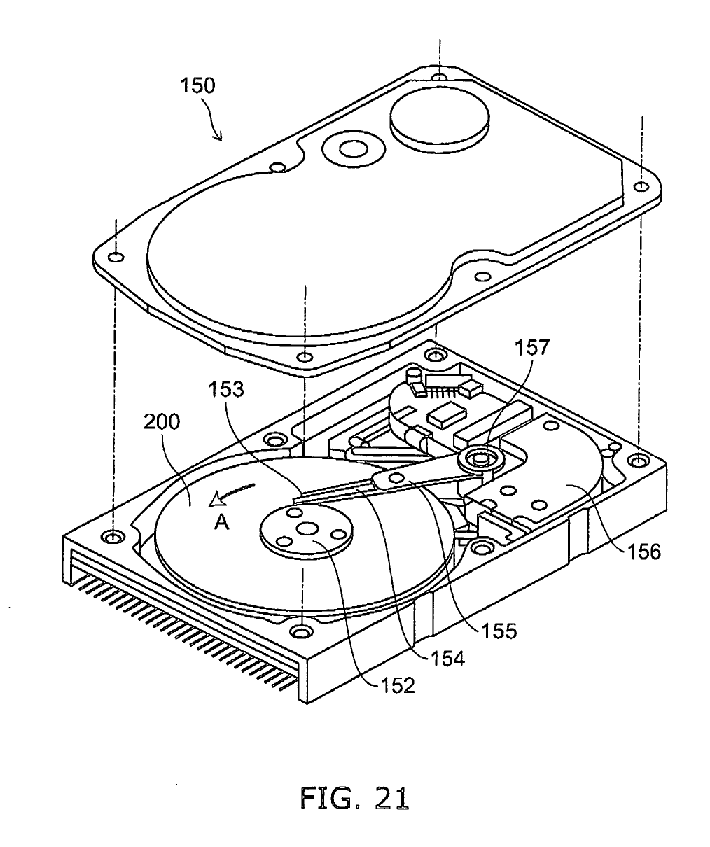

FIG. 21 is a schematic perspective view illustrating a configuration of a magnetic recording and reproducing apparatus of a fifth embodiment of this invention.

As shown in FIG. 21, a magnetic recording and reproducing apparatus 150 according to the fifth embodiment of this invention is an apparatus having a type of using a rotary actuator. In this figure, a magnetic disk 200 is loaded in a spindle motor 152, and rotates to the direction of the arrow A by a motor, which is not shown, responding to a control signal from a drive apparatus control part, which is not shown. The magnetic recording and reproducing apparatus 150 according to this embodiment may have a plurality of magnetic disks 200.

The magnetic recording and reproducing apparatus 150 includes the above-described magnetic head assembly 160 according to this invention.

That is, the head slider 153 housed in the magnetic disc 200 and performing recording and reproducing of information is attached to the forefront of the thin-filmy suspension 154.

The suspension 154 is connected to one edge of the actuator arm 155. A voice coil motor 156 being a kind of a linear motor is provided at the other edge of the actuator arm 155. The voice coil motor 156 is composed of the driving coil (not shown) wound around the bobbin portion and a magnetic circuit with a permanent magnet and a counter yoke which are disposed opposite to one another so as to sandwich the driving coil.

When the magnetic recording disk 200 is rotated, the air bearing (ABS) of the head slider 153 is held above the main surface of the magnetic recording disk 200 with a given floating distance. Alternatively, the head slider 153 may constitute a so-called “contact running type” slider such that the slider is in contact with the magnetic recording disk 200.

The actuator arm 155 is supported by ball bearings (not shown) provided at the upper portion and the bottom portion of the spindle 157 so as to be rotated and slid freely by the voice coil motor 156.

In the magnetic recording and reproducing apparatus 150 according to this embodiment, the head gimbal assembly 160 having a magnetic head including the above-described magneto-resistance effect element manufactured by at least any one of the first and the second embodiments of this invention is used, and therefore, by the high MR variation ratio, information magnetically recorded in the magnetic disk 200 with high recording density can be certainly read.

### Sixth Embodiment

Next, as a magnetic recording and reproducing apparatus according to a sixth embodiment of this invention, an example of magnetic memory in which the magneto-resistance effect element according to the embodiment of this invention is mounted will be described. That is, by using the magneto-resistance effect element according to the embodiment of this invention, a magnetic memory such as magnetic random access memory (MRAM) in which a memory cell is arranged in a matrix form can be realized. Hereinafter, the case in which the magneto-resistance effect element 101 explained in the first embodiment is used as the magneto-resistance effect element will be described, but at least any one of the above-described magneto-resistance effect elements 101, 104, and 105 explained as the embodiments and examples of this invention can be used.

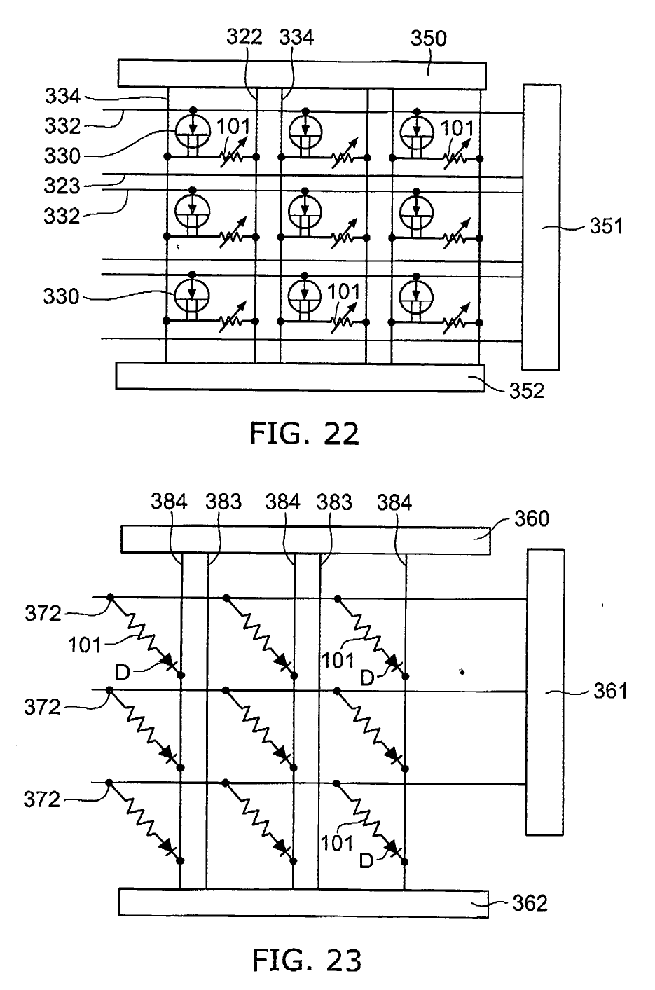

FIG. 22 is a schematic view illustrating a configuration of a magnetic recording and reproducing apparatus according to a sixth embodiment of this invention.

This drawing shows a circuit configuration when the memory cells are arranged in an array.

As shown in FIG. 22, in the magneto-resistance effect element according to the embodiment of this invention, in order to select one bit in the array, a column decoder 350 and a line decoder 351 are provided, where a switching transistor 330 is turned ON by a bit line 334 and a word line 332 and to be selected uniquely, so that the bit information recorded in a magnetic recording layer (free layer) in the magneto-resistance effect film 10 can be readout by being detected by a sense amplifier 352.

In order to write the bit information, a writing current is flowed in a specific write word line 323 and a bit line 322 to generate a magnetic field for writing.

FIG. 23 is a schematic view illustrating a configuration of another magnetic recording and reproducing apparatus according to a sixth embodiment of this invention.

As shown in FIG. 23, in this case, a bit line 372 and a word line 384 which are arranged in matrix are selected by decoders 360, 361 and 362 respectively, so that a specific memory cell in the array is selected. Each memory cell is configured such that the magneto-resistance effect element 101 and a diode D are connected in series. Here, the diode D plays a role of preventing a sense current from detouring in the memory cell other than the selected magneto-resistance effect element 101. A writing is performed by a magnetic field generated by flowing the writing current in the specific bit line 372 and the word line 383, respectively.

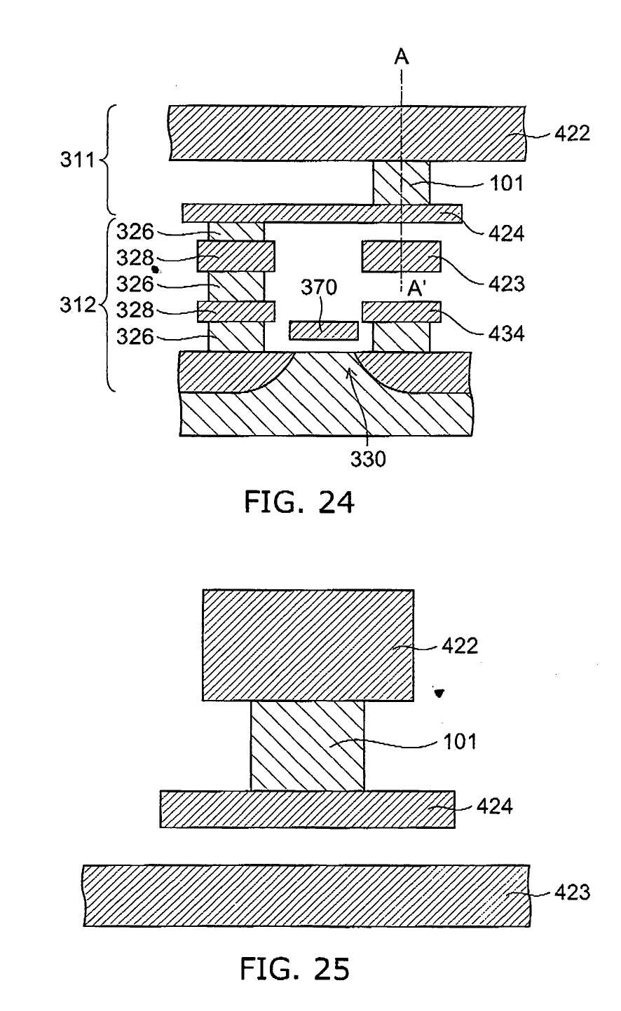

FIG. 24 is a schematic view illustrating a configuration of another magnetic recording and reproducing apparatus according to a sixth embodiment of this invention.

FIG. 25 is a schematic cross-sectional view taken on A-A′ line shown in FIG. 24.

These figures illustrate a configuration of a 1-bit memory cell included in the magnetic recording and reproducing apparatus (the magnetic memory) shown in FIG. 22. This memory cell includes a memory element part 311 and an address selection transistor part 312.

The memory element part 311 includes the magneto-resistance effect element 101 and a pair of wirings 422, 424 connected to the magneto-resistance effect element 101. The magneto-resistance effect element 101 is the magneto-resistance effect element (CCP-CPP element) as described in the above embodiments.

Meanwhile, in the address selection transistor part 312, a switching transistor 330 having connection therewith via a via 326 and an embedded wiring 328 is provided. The switching transistor 330 performs switching operations in accordance with voltages applied to a gate 370 to control the opening/closing of the current path between the magneto-resistance effect element 101 and the wiring 434.

Further, below the magneto-resistance effect element 101, a wire 423 for writing is provided in the direction that is about perpendicular to the wire 422. These wires 422 and 423 can be formed by aluminum (Al), copper (Cu), tungsten (W), tantalum (Ta) or an alloy including any one thereof.

The above-described wire 422 corresponds to the bit line and the wire 423 corresponds to the word line 323.

In the memory cell having such a configuration, when writing bit information into the magneto-resistance effect element 101, a writing pulse current is flowed in the wirings 422 and 423, and a synthetic magnetic field induced by the writing current is applied to appropriately invert the magnetization of a recording layer of the magneto-resistance effect element 101.

Further, when reading out the bit information, a sense current is flowed through the wiring 422, the magneto-resistance effect element 101 including the magnetic recording layer and the wiring 424 to measure a resistance value of or a fluctuation in the resistance values of the magneto-resistance effect element 101.

The magnetic memory according to the embodiment of this invention can assure writing and reading by surely controlling the magnetic domain of the recording layer even though the cell is miniaturized in size, with the use of the magneto-resistance effect element (CCP-CPP element) with the above-described embodiment.

This invention is not limited to the above disclosure and every kind of variation and modification may be made without departing from the scope of the present invention. The concrete structure of the magneto-resistance effect element, and the shape and material of the electrodes, the magnetic field biasing films and the insulating layer can be appropriately selected among the ones well known by the person skilled in the art. In these cases, the intended magneto-resistance effect element by using the present invention can be obtained so as to exhibit the same effect/function as described above. When the magneto-resistance effect element is applied for a reproducing magnetic head, the detecting resolution of the magnetic head can be defined by applying magnetic shielding for the upper side and the lower side of the magneto-resistance effect element.

Moreover, the magneto-resistance effect element can be applied for both of a longitudinal magnetic recording type magnetic head and a vertical magnetic recording type magnetic recording type magnetic head. Also, the magneto-resistance effect element can be applied for both of a longitudinal magnetic recording/reproducing device and a vertical magnetic recording/reproducing device. The magnetic recording/reproducing device may be a so-called stationary type magnetic device where a specific recording medium is installed therein or a so-called removable type magnetic device where a recording medium can be replaced.

As described above, the embodiments of the invention have been described with reference to specific examples. However, the invention is not limited to these specific examples. For example, the specific configuration of each of components constituting the method for manufacturing a magneto-resistance effect element and the magnetic recording and reproducing apparatus are included in the scope of the invention, as long as the invention can be carried out in the same manner and the same effect can be obtained by appropriately selecting the components from the known range by those skilled in the art.

Moreover, combination of two or more components of each of the specific examples in the technically possible range is included in the scope of the invention as long as including the spirit of the invention.

In addition, all of the method for manufacturing a magneto-resistance effect element and the magnetic recording and reproducing apparatus that can be appropriately design-modified and carried out by those skilled in the art on the basis of the method for manufacturing a magneto-resistance effect element and the magnetic recording and reproducing apparatus described above as the embodiments of the invention belong to the invention as long as including the spirit of the invention.

In addition, it is understood that those skilled in the art can achieve various variations and modifications and modifications and that the variations and the modifications belong to the scope of the invention.

1. A method for manufacturing a magneto-resistance effect element having a first magnetic layer including a ferromagnetic material, a second magnetic layer including a ferromagnetic material and a spacer layer provided between the first magnetic layer and the second magnetic layer, the spacer layer having an insulating layer and a conductive portion penetrating through the insulating layer, the method comprising:
forming a film to be a base material of the spacer layer;
performing a first treatment using a gas including at least one of oxygen molecules, oxygen atoms, oxygen ions, oxygen plasma and oxygen radicals on the film; and
performing a second treatment using a gas including at least one of helium ions, helium plasma, helium radicals, neon ions, neon plasma and neon radicals on the film submitted to the first treatment.

2. The method according to claim 1, wherein the second treatment includes a treatment of introducing at least one of helium gas and neon gas in an atmosphere achieved by ionizing or forming plasma of a gas including argon.

3. The method according to claim 1, wherein the second treatment includes a treatment of irradiating the film with at least one of helium gas and neon gas ionized or formed into plasma, the film being submitted to the first treatment.

4. The method according to claim 1, wherein the second treatment is performed while heating the film submitted to the first treatment.

5. The method according to claim 1, further comprising: performing a third treatment including at least one of irradiating the film with irradiating with argon ions, irradiating the film with argon plasma and heating the film, the film being submitted to the second treatment.

6. The method according to claim 5, wherein a combination of the performing the second treatment and the performing the third treatment is repeated plural times.

7. The method according to claim 5, wherein a combination of the forming the film, the performing the first treatment, the performing the second treatment and the performing the third treatment is repeated plural times.

8. The method according to claim 5, further comprising: performing a fourth treatment using a gas including at least one of oxygen molecules, oxygen atoms, oxygen ions, oxygen plasma and oxygen radicals to the film, the film being submitted to the third treatment.

9. The method according to claim 1, wherein a combination of the forming the film, the performing the first treatment and the performing the second treatment is repeated plural times.

10. The method according to claim 1, wherein a combination of the forming the film and the performing the first treatment is repeated plural times.

11. The method according to claim 1, wherein the forming the film includes forming a first metallic film and a second metallic film, and the performing the first treatment includes exposing the second metallic film to oxidizing gas.

12. The method according to claim 1, wherein the forming the film includes forming a first metallic film and a second metallic film, and the performing the first treatment includes providing oxygen gas to the second metallic film, the oxygen gas being introduced in an atmosphere achieved by ionizing or forming plasma of a gas including at least one selected from the group consisting of argon, xenon, helium, neon and krypton.

13. The method according to claim 1, wherein
the forming the film includes forming a first metallic film and a second metallic film, and
the performing first treatment includes:
performing a pretreatment of irradiating the second metallic film with a gas ionized or formed into plasma, the gas including at least one selected from the group consisting of argon, xenon, helium, neon and krypton; and
providing the oxygen gas to the second metallic film submitted to the pretreatment, the oxygen gas being introduced in an atmosphere achieved by ionizing or forming plasma of a gas including at least one selected from the group consisting of argon, xenon, helium, neon and krypton.

14. The method according to claim 13, wherein the first metallic film includes at least one selected from the group consisting of Cu, Au, Ag and Al, and the second metallic film includes at least one selected from the group consisting Al, Si, Mg, Ti, Hf, Zr, Cr, Mo, Nb and W.

15. The method according to claim 5, wherein a high frequency bias configured to generate the rare gas ions or the rare gas plasma in the third treatment has a power from 5 W to 120 W inclusive.

16. The method according to claim 5, wherein an irradiation time of the rare gas ions or the rare gas plasma in the third treatment is from 5 seconds to 5 minutes inclusive.

17. A magnetic recording and reproducing apparatus comprising:
a magnetic head assembly including a suspension, a the magneto-resistance effect element being mounted on one end of the suspension, and an actuator arm connected to other end of the suspension; and
a magnetic recording medium, information being recorded in the magnetic recording medium by using the magneto-resistance effect element,
the magneto-resistance effect element having a first magnetic layer including a ferromagnetic material, a second magnetic layer including a ferromagnetic material and a spacer layer provided between the first magnetic layer and the second magnetic layer, the spacer layer having an insulating layer and a conductive portion penetrating through the insulating layer,
the magneto-resistance effect device being manufactured by a method including:
forming a film to be a base material of the spacer layer;
performing a first treatment using a gas including at least one of oxygen molecules, oxygen atoms, oxygen ions, oxygen plasma and oxygen radicals on the film; and
performing a second treatment using a gas including at least one of helium ions, helium plasma, helium radicals, neon ions, neon plasma and neon radicals on the film submitted to the first treatment.
